(19) United States
(12) Patent Application Publication
(10) Pub. No.: US 2016/0035814 A1
(43) Pub. Date: Feb. 4, 2016

(54) ORGANIC LIGHT EMITTING DIODE DISPLAY AND METHOD FOR MANUFACTURING THE SAME

(71) Applicant: SAMSUNG DISPLAY CO., LTD., Yongin-City (KR)

(72) Inventors: Guang Hai JIN, Seoul (KR); Won Kyu LEE, Seoul (KR)

(21) Appl. No.: 14/679,350

(22) Filed: Apr. 6, 2015

(30) Foreign Application Priority Data
Aug. 4, 2014 (KR) 10-2014-0099952

(51) Int. Cl. H01L 27/32; H01L 51/56; H01L 29/786; H01L 29/66

(52) U.S. Cl. CPC H01L 27/3276; H01L 27/3248; H01L 27/3262; H01L 27/3265; H01L 27/3246; H01L 29/66757; H01L 51/56; H01L 29/78696; H01L 2227/323

(57) ABSTRACT

An organic light emitting device includes a switching transistor and a driving transistor. A semiconductor layer is commonly used by the switching and driving transistors. The portion of semiconductor layer corresponding to the driving transistor is curved. A gate insulating layer is located between a channel region and gate electrode of the switching transistor, and between the channel region and the gate electrode of the driving transistor. The gate insulating layer has substantially a same plane shape as the switching gate electrode and the driving gate electrode. An edge of the gate insulating layer and an edge of the switching and driving gate electrodes at least partially overlap.

### CROSS-REFERENCE TO RELATED APPLICATION

Korean Patent Application No. 10-2014-0099952 filed on, Aug. 4, 2014, and entitled: “Organic Light Emitting Diode Display and Method for Manufacturing the Same” is incorporated by reference herein in its entirety.

### BACKGROUND

1. Field

One or more embodiments described herein relate to an organic light emitting device and a method of manufacturing the same.

2. Description of the Related Art

An organic light emitting display generates images using pixels that include organic light emitting diodes (OLEDs). Because this type of display is self-emitting, it does not require a separate light source like a liquid crystal display. Also, the thickness and weight of this type of display may be less than other display technologies. Also, an organic light emitting display has high quality characteristics such as low power consumption, high luminance, and a high reaction speed. As a result, this type of display is often used in portable electronic devices.

An OLED display may be formed by a photolithography process that uses a plurality of masks. As the number of mask processes increases, process time and process production costs may increase.

### SUMMARY

In accordance with one embodiment, an organic light emitting device includes a substrate, a scan line and a previous scan line on the substrate to respectively transmit a scan signal and a previous scan signal, a data line and a driving voltage line insulated from and intersecting the scan line and the previous scan line, the data line and the driving voltage line to respectively transmit a data signal and a driving voltage, a switching transistor connected to the scan line and the data line, the switching transistor including a switching semiconductor layer, a switching channel region, and a switching gate electrode, a driving transistor connected to the switching transistor and including a driving semiconductor layer, a driving channel region, and a driving gate electrode, the driving semiconductor layer and the switching semiconductor layer formed of a same layer, a first gate insulating layer, and an organic light emitting diode connected to the driving transistor.

The driving semiconductor layer is curved. The first gate insulating layer is between the switching channel region and the switching gate electrode and between the driving channel region and the driving gate electrode. The first gate insulating layer has substantially a same plane shape as the switching gate electrode and the driving gate electrode. An edge of the first gate insulating layer and an edge of the switching gate electrode and the driving gate electrode at least partially overlap.

The device may include a second gate insulating layer on the substrate including the switching gate electrode and the driving gate electrode; and a first connector formed with a same layer as the data line, wherein the first connector connects the scan line on the second gate insulating layer and the switching gate electrode on the first gate insulating layer through a contact hole. The previous scan line may be on the second gate insulating layer, and the driving gate electrode may be connected to the previous scan line.

The device may include an initialization transistor to turn on based on a previous scan signal from the previous scan line and to transmit an initialization voltage to the driving gate electrode; and a second connector formed with the same layer as the data line, wherein the second connector connects the previous scan line and the initialization gate electrode of the initialization transistor through a contact hole.

The device may include a passivation layer on the data line and the driving voltage line and having an opening, and the organic light emitting diode includes a first electrode at a boundary line of the opening and electrically connected to the driving transistor, an organic emission layer on the first electrode, and a second electrode on the organic emission layer.

The device may include an emission control line on the second gate insulating layer; a third connector and a fourth connector formed with the same layer as the data line; an operation control transistor to turn on based on an emission control signal transmitted to the emission control line and to transmit a driving voltage transmitted by the driving voltage line to the driving transistor; and an emission control transistor to turn on by the emission control signal and to transmit the driving voltage from the driving transistor to the organic light emitting diode, wherein the third connector connects the emission control line and the gate electrode of the operation control transistor through the contact hole, and the fourth connector connects the emission control line and the gate electrode of the emission control transistor through the contact hole.

The first electrode may be connected to the drain electrode of the emission control transistor through the contact hole in the passivation layer. The device may include an initialization voltage line on the second gate insulating layer, wherein the initialization voltage line is to transmit an initialization voltage to initialize the driving transistor. The semiconductor layer of the driving transistor, the switching transistor, the operation control transistor, and the emission control transistor may be connected.

The device may include a storage capacitor including a first plate on the first gate insulating layer and overlapping the driving semiconductor layer, and a second plate on the second gate insulating layer covering the first storage capacitor plate and overlapping the first storage capacitor plate, wherein the second plate is the driving gate electrode.

In accordance with another embodiment, a method for manufacturing an organic light emitting device including depositing a polysilicon layer, an amorphous silicon layer, and a metal layer on a substrate; forming a first photosensitive film pattern on the metal layer, the first photosensitive film including a first portion and a second portion thicker than the first portion; etching the metal layer, the amorphous silicon layer, and the polysilicon layer using the first photosensitive film pattern as a mask to form a metal layer pattern, an insulating layer pattern, and a semiconductor layer; etching the exposed metal layer and insulating layer pattern using the second portion as a mask after removing the first portion to form a driving gate electrode, a switching gate electrode, and a first gate insulating layer; doping an impurity into the semiconductor layer after removing the first photosensitive film pattern to form a source region and a drain region; forming a second gate insulating layer on the driving gate electrode and the switching gate electrode; forming a scan line and a previous scan line on the second gate insulating layer; forming an interlayer insulating layer on the scan line and the previous scan line; and forming a first connector connecting the scan line and the switching gate electrode through a contact hole and a data line and a driving voltage line intersecting the scan line and the previous scan line on the interlayer insulating layer.

The method may include, after forming the data line and the driving voltage line, forming a passivation layer on the data line and the driving voltage line; forming a first electrode receiving a driving signal from the driving voltage line on the passivation layer; forming a pixel definition layer having an opening exposing the first electrode on the first electrode; forming an organic emission layer in the opening; and forming a second electrode on the organic emission layer.

The method may include etching the metal layer and the insulating layer pattern using the second portion as a mask to form an initialization gate electrode; and forming a second connector connecting the previous scan line and the initialization gate electrode through a contact hole on the interlayer insulating layer.

The method may include etching the exposed metal layer and insulating layer pattern using the second portion as a mask to form an operation control gate electrode and an emission control gate electrode; forming an emission control line on the second gate insulating layer; and forming a third connector connecting the emission control line and the operation control gate electrode through a contact hole and a fourth connector connecting the emission control line and the emission control gate electrode through a contact hole on the interlayer insulating layer.

The method may include, after forming the data line and the driving voltage line, forming a passivation layer on the data line and the driving voltage line; forming a second photosensitive film pattern on the passivation layer, the second photosensitive film including a third portion and a fourth portion thicker than the third portion; etching the exposed passivation layer using the second photosensitive film pattern as a mask to form a contact hole for a pixel exposing the emission control gate electrode; removing a portion of the passivation layer using the fourth portion as a mask after removing the third portion to form an opening; forming a first electrode in the opening; forming an organic emission layer on the first electrode; and forming a second electrode on the organic emission layer.

In accordance with another embodiment, a pixel includes a switching transistor connected to a scan line and data line, the switching transistor including a switching semiconductor layer, a switching channel region, and a switching gate electrode; and a driving transistor connected to the switching transistor and including a driving semiconductor layer, a driving channel region, and a driving gate electrode, wherein the driving semiconductor layer and the switching semiconductor layer correspond to different regions of a same first layer, and wherein the switching gate electrode and the driving gate electrode correspond to different regions of a same second layer on the first layer. The driving semiconductor layer may have a non-linear shape.

The pixel may include a gate insulating layer to insulate the switching and driving gate electrodes, wherein the first gate insulating layer has substantially a same shape as the switching and driving gate electrodes. The gate insulating layer may have substantially a same shape as the switching gate electrode and the driving gate electrode. An edge of the gate insulating layer and an edge of the switching gate electrode and the driving gate electrode may at least partially overlap.

### BRIEF DESCRIPTION OF THE DRAWINGS

Features will become apparent to those of skill in the art by describing in detail exemplary embodiments with reference to the attached drawings in which:

FIG. 1 illustrates an embodiment of a pixel of an organic light emitting display;

FIG. 2 illustrates a schematic view of the pixel;

FIG. 3 illustrates a detailed layout view of the pixel in FIG. 2;

FIG. 4 illustrates a view along section line IV-IV in FIG. 3;

FIG. 5 illustrates a view along section lines V-V′ and V′-V″ in FIG. 3;

FIGS. 6 and 7 illustrate an operation in an embodiment for manufacturing an organic light emitting display;

FIG. 8 illustrates a layout view of a subsequent operation;

FIG. 9 illustrates a view along section line IX-IX in FIG. 8;

FIG. 10 illustrates a view along section lines X-X′ and X′-X″ of FIG. 8;

FIG. 11 illustrates a layout view of an operation following that of FIG. 8;

FIG. 12 illustrates a view along section line XII-XII in FIG. 11;

FIG. 13 illustrates a view along section lines XIII-XIII′ and XIII′-XIII″ in FIG. 11;

FIG. 14 illustrates a layout view of an operation following that of FIG. 11;

FIG. 15 illustrates a view along section line XV-XV in FIG. 14;

FIG. 16 illustrates a view along section lines XVI-XVI′ and XVI′-XVI″ in FIG. 14;

FIG. 17 illustrates a layout view of an operation following that of FIG. 14;

FIG. 18 illustrates a view along section line XVIII-XVIII in FIG. 17;

FIG. 19 illustrates a view along section lines XIX-XIX′ and XIX′-XIX″ in FIG. 17;

FIG. 20 illustrates another embodiment of an organic light emitting display;

FIG. 21 illustrates a view along section line XXI-XXI in FIG. 20;

FIG. 22 illustrates a view along line XXII-XXII′ and XXII′-XXII″ in FIG. 20;

FIG. 23 illustrates an operation in another embodiment of a method for manufacturing an organic light emitting display;

FIG. 24 illustrates a view along section line XXIV-XXIV in FIG. 23;

FIG. 25 illustrates a view along section lines XXV-XXV′ and XXV-XXV″ in FIG. 23;

FIG. 26 illustrates a layout view of an operation following FIG. 23;

FIG. 27 illustrates a view along section line XXVII-XXVII in FIG. 26;

FIG. 28 illustrates a view along section lines XXVIII-XXVIII′ and XXVIII′-XXVIII″ in FIG. 26;

FIG. 29 illustrates a layout view of an operation following FIG. 27; and

FIG. 30 illustrates a layout view of an operation following FIG. 28.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In the drawings, the thickness of layers, films, panels, regions, etc., are exaggerated for clarity. In the drawings, the thicknesses of some layers and areas are exaggerated for convenience of explanation. It will be understood that when an element such as a layer, film, region, or substrate is referred to as being “on” another element, it can be directly on the other element or intervening elements may also be present.

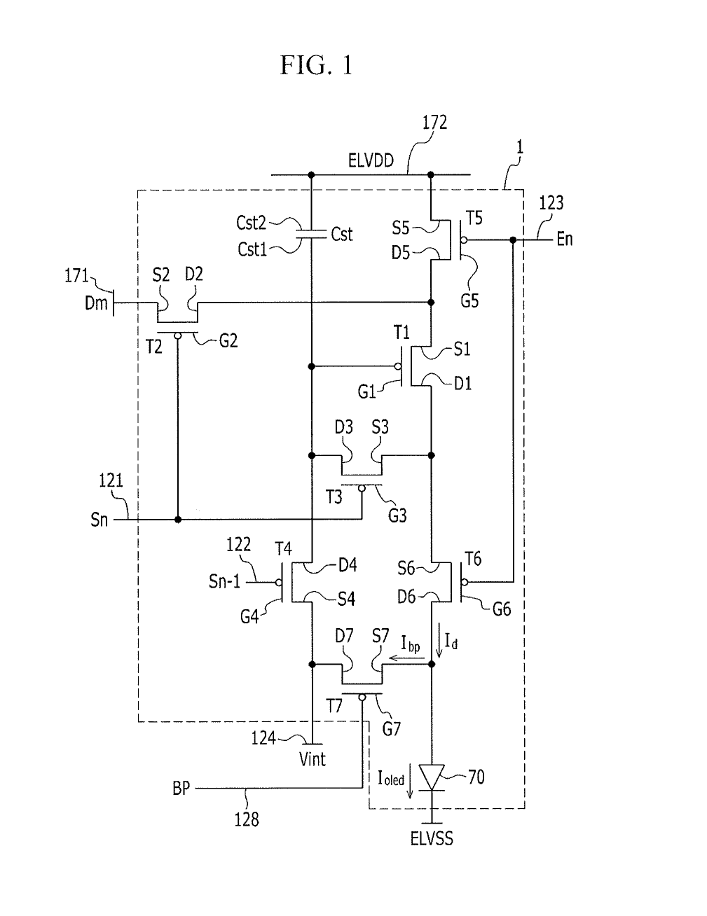

FIG. 1 illustrates an embodiment of a pixel 1 of an organic light emitting display. As shown in FIG. 1, the pixel 1 includes a plurality of signal lines 121, 122, 123, 124, 128, 171, and 172, a plurality of thin film transistors T1, T2, T3, T4, T5, T6, and T7 connected to the plurality of signal lines, a storage capacitor Cst, and an organic light emitting diode 70.

The thin film transistors include a driving thin film transistor T1, a switching thin film transistor T2, a compensation thin film transistor T3, an initialization thin film transistor T4, an operation control thin film transistor T5, an emission control thin film transistor T6, and a bypass thin film transistor T7.

The signal lines include a scan line 121 transferring a scan signal Sn, a previous scan line 122 transferring a previous scan signal Sn−1 to the initialization thin film transistor T4, an emission control line 123 transferring an emission control signal En to the operation control thin film transistor T5 and the emission control thin film transistor T6, an initialization voltage line 124 transferring an initialization voltage Vint initializing the driving thin film transistor T1, a bypass control line 128 transferring a bypass signal BP to the bypass thin film transistor T7, a data line 171 crossing the scan line 121 and transferring a data signal Dm, and a driving voltage line 172 transferring a driving voltage ELVDD and formed substantially parallel with the data line 171.

A gate electrode G1 of the driving thin film transistor T1 is connected to one end Cst1 of the storage capacitor Cst. A source electrode S1 of the driving thin film transistor T1 is connected with the driving voltage line 172 via the operation control thin film transistor T5. A drain electrode D1 of the driving thin film transistor T1 is electrically connected with an anode of the organic light emitting diode OLED via the emission control thin film transistor T6. The driving thin film transistor T1 receives the data signal Dm according to a switching operation of the switching thin film transistor T2, to supply a driving current Id to the organic light emitting diode 70.

A gate electrode G2 of the switching thin film transistor T2 is connected with the scan line 121. A source electrode S2 of the switching thin film transistor T2 is connected with the data line 171. A drain electrode D2 of the switching thin film transistor T2 is connected with the source electrode S1 of the driving thin film transistor T1 and is connected with the driving voltage line 172 via the operation control thin film transistor T5. The switching thin film transistor T2 is turned on, according to the scan signal Sn received through the scan line 121, to perform a switching operation of transferring the data signal Dm transferred to the data line 171 to the source electrode of the driving thin film transistor T1.

A gate electrode G3 of the compensation thin film transistor T3 is directly connected with the scan line 121. A source electrode S3 of the compensation thin film transistor T3 is connected to the drain electrode D1 of the driving thin film transistor T1 and is connected with an anode of the organic light emitting diode OLED via the emission control thin film transistor T6. A drain electrode D3 of the compensation thin film transistor T3 is connected with one end Cst1 of the storage capacitor Cst and the drain electrode D4 of the initialization thin film transistor T4, and the gate electrode G1 of the driving thin film transistor T1 together. The compensation thin film transistor T3 is turned on according to the scan signal Sn received through the scan line 121, to connect the gate electrode G1 and the drain electrode D1 of the driving thin film transistor T1 and diode-connect the driving thin film transistor T1.

A gate electrode G4 of the initialization thin film transistor T4 is connected with the previous scan line 122. A source electrode S4 of the initialization thin film transistor T4 is connected with the initialization voltage line 124. A drain electrode D4 of the initialization thin film transistor T4 is connected with one end Cst1 of the storage capacitor Cst, the drain electrode D3 of the compensation thin film transistor T3, and the gate electrode G1 of the driving thin film transistor T1 together. The initialization thin film transistor T4 is turned on according to the previous scan signal Sn−1 received through the previous scan line 122, to transfer the initialization voltage Vint to the gate electrode G1 of the driving thin film transistor T1 and to then perform an initialization operation of initializing a voltage of the gate electrode G1 of the driving thin film transistor T1.

A gate electrode G5 of the operation control thin film transistor T5 is connected with the emission control line 123. A source electrode S5 of the operation control thin film transistor T5 is connected with the driving voltage line 172. A drain electrode D5 of the operation control thin film transistor T5 is connected with the source electrode S1 of the driving thin film transistor T1 and the drain electrode S2 of the switching thin film transistor T2.

A gate electrode G6 of the emission control thin film transistor T6 is connected with the emission control line 123. A source electrode S6 of the emission control thin film transistor T6 is connected with the drain electrode D1 of the driving thin film transistor T1 and the source electrode S3 of the compensation thin film transistor T3. A drain electrode D6 of the emission control thin film transistor T6 is electrically connected with an anode of the organic light emitting diode 70. The operation control thin film transistor T5 and the emission control thin film transistor T6 are simultaneously turned on according to the emission control signal En received through the emission control line 123. The driving voltage ELVDD is transferred to the organic light emitting diode 70, and thus an emission current Ioled flows in the organic light emitting diode 70.

A gate electrode G7 of the bypass thin film transistor T7 is connected to a bypass control line 128. A source electrode S7 of the bypass thin film transistor T7 is connected with the drain electrode D6 of the emission control transistor T6 and an anode of the organic light emitting diode OLED together. A drain electrode D7 of the bypass thin film transistor T7 is connected with the initialization voltage line 124 and the source electrode S4 of the initialization thin film transistor T4 together.

The other end Cst2 of the storage capacitor Cst is connected with the driving voltage line 172. A cathode of the organic light emitting diode 70 is connected with a common voltage ELVSS. As a result, the organic light emitting diode OLED receives the emission current Ioled from the driving thin film transistor T1 to emit light, thereby displaying an image.

Operation of the pixel according to one embodiment will now be described for a plurality of periods. First, for an initializing period, the previous scan signal Sn−1 having a low level is supplied through the previous scan line 122. Then, the initialization thin film transistor T4 is turned on in response to the previous scan signal Sn−1 having the low level, the initialization voltage Vint is connected to the gate electrode of the driving thin film transistor T1 through the initialization thin film transistor T4 from the initialization voltage line 124, and the driving thin film transistor T1 is initialized by the initialization voltage Vint.

Thereafter, for a data programming period, the scan signal Sn having the low level is supplied through the scan line 121. Then, the switching thin film transistor T2 and the compensation thin film transistor T3 are turned on in response to the scan signal Sn having the low level. In this case, the driving thin film transistor T1 is diode-connected by the turned-on compensation thin film transistor T3 and biased in a forward direction.

Then, a compensation voltage Dm+Vth (Vth is a negative (−) value), reduced by a threshold voltage Vth of the driving thin film transistor T1 from a data signal Dm supplied from the data line 171, is applied to the gate electrode of the driving thin film transistor T1.

The driving voltage ELVDD and the compensation voltage Dm+Vth are applied to respective ends of the storage capacitor Cst. A charge corresponding to a voltage difference between the respective ends is stored in the storage capacitor Cst. Thereafter, for an emission period, the emission control signal En supplied from the emission control line 123 is changed from the high level to the low level. Then, the operation control thin film transistor T5 and the emission control thin film transistor T6 are turned on by the emission control signal En of the low level for the emission period.

Then, a driving current ld is generated based on a voltage difference between the voltage of the gate electrode of the driving thin film transistor T1 and the driving voltage ELVDD. The driving current ld is supplied to the organic light emitting diode 70 through the emission control thin film transistor T6. The gate-source voltage Vgs of the driving thin film transistor T1 is maintained as ‘(Dm+Vth)−ELVDD’ by the storage capacitor Cst for the emission period. Also, based on a current-voltage relationship of the driving thin film transistor T1, the driving current ld is proportional to the square ‘(Dm−ELVDD)²’ of a value obtained by subtracting the threshold voltage from the source-gate voltage. Accordingly, the driving current ld is determined regardless of the threshold voltage Vth of the driving thin film transistor T1.

In this case, the bypass thin film transistor T7 receives a bypass signal BP from the bypass control line 128. The bypass signal BP is a voltage having a predetermined level which always turns off the bypass thin film transistor T7. The bypass thin film transistor T7 receives a voltage having a transistor off level from the gate electrode G7. Thus, the bypass transistor T7 is always turned off and part of the driving current ld flows out through bypass thin film transistor T7 as a bypass current Ibp in the off state.

Accordingly, when the driving current displaying a black image flows, the emission current Ioled of the organic light emitting diode (which is reduced by the current amount of the bypass current Ibp which flows out from the driving current ld through the bypass thin film transistor T7) has a minimum current amount at a level which may exactly express the black image. Therefore, a black luminance image is exactly implemented using the bypass thin film transistor T7, to improve contrast ratio.

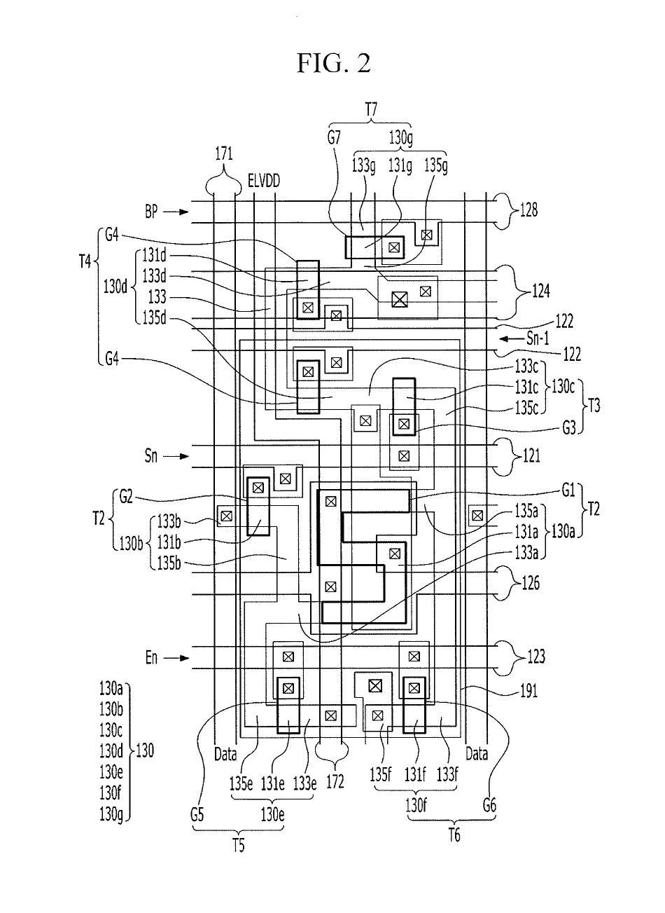

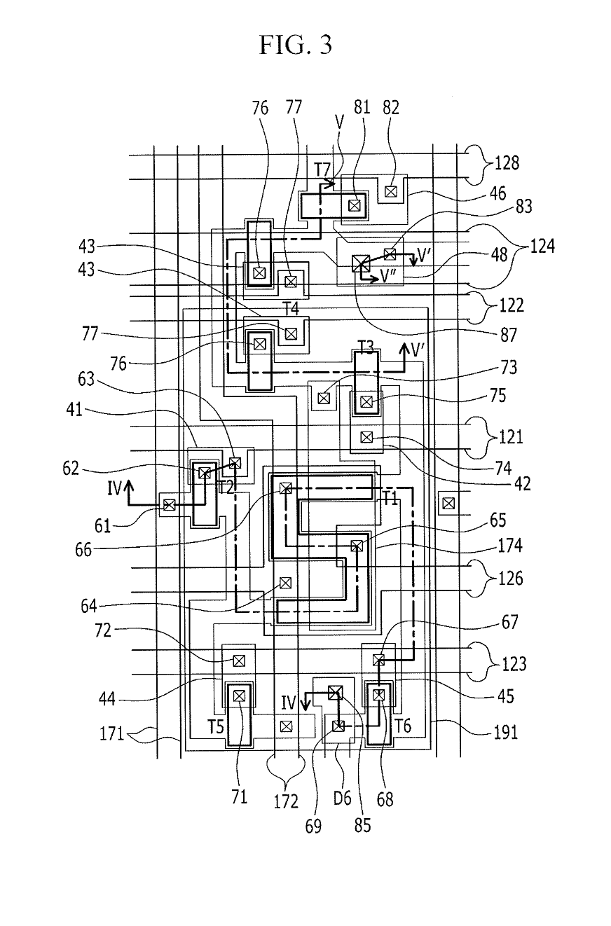

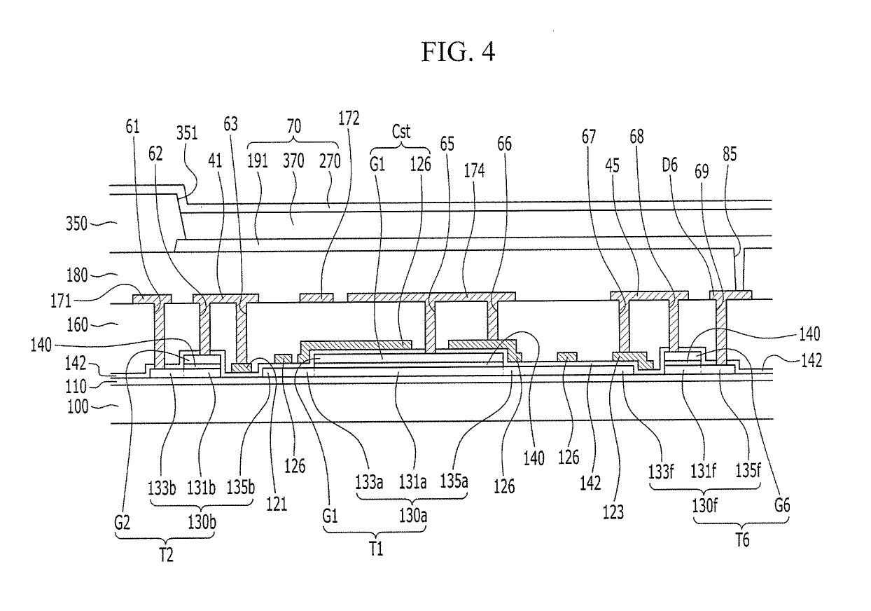

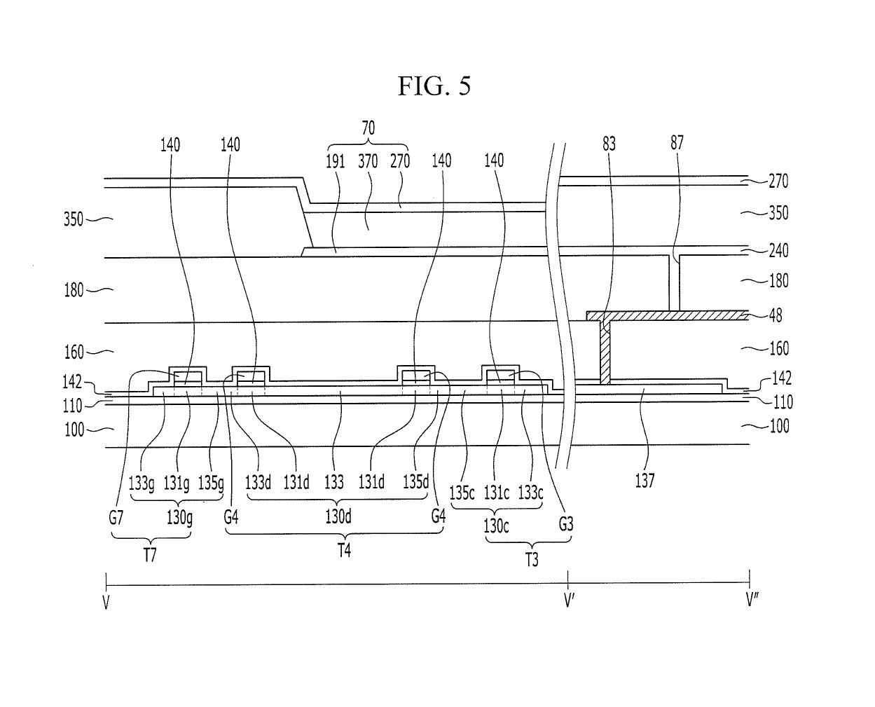

FIG. 2 illustrates an embodiment of the pixel including a plurality of transistors and capacitors, FIG. 3 is a layout view of the pixel in FIG. 2, FIG. 4 is a cross-sectional view of the pixel in FIG. 3 taken along a line IV-IV, and FIG. 5 is a cross-sectional view of the pixel in FIG. 3 taken along lines V-V′ and V′-V″.

As illustrated in FIG. 2, a pixel of the pixel part P1 includes a scan line 121, a previous scan line 122, an emission control line 123, and a bypass control line 128 which respectively apply a scan signal Sn, a previous scan signal Sn−1, an emission control signal En, and a bypass signal BP. These lines are formed in a row direction. A data line 171 and a driving voltage line 172 cross the scan line 121, the previous scan line 122, the emission control line 123, and the bypass control line 128, and respectively apply a data signal Dm and a driving voltage ELVDD to the pixel. The initialization voltage Vint is transferred to the driving thin film transistor T1, via the initialization thin film transistor T4, from the organic light emitting diode 70 through the initialization voltage line 124.

The pixel also includes a driving thin film transistor T1, a switching thin film transistor T2, a compensation thin film transistor T3, an initialization thin film transistor T4, a operation control thin film transistor T5, an emission control thin film transistor T6, a bypass thin film transistor T7, a storage capacitor Cst, and an organic light emitting diode OLED.

The driving thin film transistor T1, the switching thin film transistor T2, the compensation thin film transistor T3, the initialization thin film transistor T4, the operation control thin film transistor T5, the emission control thin film transistor T6, and the bypass thin film transistor T7 are formed along a semiconductor layer 130, and the semiconductor layer 130 may have one of a variety of curved or other predetermined shapes.

The semiconductor layer 130 may include, for example, polysilicon or an oxide semiconductor. The oxide semiconductor may include, for example, one of oxide based on titanium (Ti), hafnium (Hf), zirconium (Zr), aluminum (Al), tantalum (Ta), germanium (Ge), zinc (Zn), gallium (Ga), tin (Sn), or indium (In), such as zinc oxide (ZnO), indium-gallium-zinc oxide (InGaZnO4), indium-zinc oxide (Zn—In—O), zinc-tin oxide (Zn—Sn—O), indium-gallium oxide (In—Ga—O), indium-tin oxide (In—Sn—O), indium-zirconium oxide (In—Zr—O), indium-zirconium-zinc oxide (In—Zr—Zn—O) indium-zirconium-tin oxide (In—Zr—Sn—O), indium-zirconium-gallium oxide (In—Zr—Ga—O), indium-aluminum oxide (In—Al—O), indium-zinc-aluminum oxide (In—Zn—Al—O), indium-tin-aluminum oxide (In—Sn—Al—O), indium-aluminum-gallium oxide (In—Al—Ga—O), indium-tantalum oxide (In—Ta—O), indium-tantalum-zinc oxide (In—Ta—Zn—O), indium-tantalum-tin oxide (In—Ta—Sn—O), indium-tantalum-gallium oxide (In—Ta—Ga—O), indium-germanium oxide (In—Ge—O), indium-germanium-zinc oxide (In—Ge—Zn—O), indium-germanium-tin oxide (In—Ge—Sn—O), indium-germanium-gallium oxide (In—Ge—Ga—O), titanium-indium-zinc oxide (Ti—In—Zn—O), or hafnium-indium-zinc oxide (Hf—In—Zn—O) which are complex oxides thereof. When the semiconductor layer 130 includes an oxide semiconductor, a separate passivation layer may be added in order to protect the oxide semiconductor, that may be vulnerable to various external environmental influences such as high temperature.

The semiconductor layer 130 includes a channel region having a channel doped with an N-type impurity or a P-type impurity, and a source region and a drain region formed at respective sides of the channel region. The source and drain regions may be formed by doping a doping impurity, which is an opposite type to the doping impurity doped in the channel region.

A planar structure of the organic light emitting display according to one embodiment will now be described with reference to FIGS. 2 and 3. A cross-sectional structure is described in detail with reference to FIGS. 4 and 5.

First, as illustrated in the embodiment of FIGS. 2 and 3, the pixel 1 includes the driving thin film transistor T1, the switching thin film transistor T2, the compensation thin film transistor T3, the initialization thin film transistor T4, the operation control thin film transistor T5, the emission control thin film transistor T6, the bypass thin film transistor T7, the storage capacitor Cst, and the organic light emitting diode 70. The transistors T1, T2, T3, T4, T5, T6, and T7 are formed along semiconductor layer 130.

The semiconductor layer 130 includes a driving semiconductor layer 130a formed in the driving thin film transistor T1, a switching semiconductor layer 130b formed in the switching thin film transistor T2, a compensation semiconductor layer 130c formed in the compensation thin film transistor T3, an initialization semiconductor layer 130d formed in the initialization thin film transistor T4, an operation control semiconductor layer 131e formed in the operation control thin film transistor T5, an emission control semiconductor layer 130f formed in the emission control thin film transistor T6, and a bypass semiconductor layer 130g formed in the bypass thin film transistor T7.

The thin film driving transistor T1 includes a driving semiconductor layer 130a, a driving gate electrode G1, a driving source electrode S1, and a driving drain electrode D1.

The driving semiconductor layer 130a is curved and, for example, may have an oblique shape or a zigzag shape. As such, the curved driving semiconductor layer 130a is formed, and thus the driving semiconductor layer 130a may be elongated in a narrow space. Also, because a driving channel region 131a of the driving semiconductor layer 130a may be elongated, a driving range of the gate voltage applied to the driving gate electrode G1 may be increased. Because the driving range of a gate voltage is increased, a gray level of light emitted from the organic light emitting diode 70 may be more finely controlled by changing a magnitude of the gate voltage, thereby enhancing resolution of the organic light emitting diode display and improving display quality. The shape of such a driving semiconductor layer 130a may be formed in various ways, e.g., ‘reverse S’, ‘S’, ‘M’, ‘W’ shapes or another predetermined shape.

The driving source electrode S1 corresponds to a driving source region 133a, which is doped with the impurity in the driving semiconductor layer 130a. The driving drain electrode D1 corresponds to a driving drain region 135a, which is doped with the impurity in the driving semiconductor layer 130a. The semiconductor layer, positioned between the driving drain region 135a and the driving source region 133a, becomes the driving channel region 131a. The driving gate electrode G1 partially or completely overlaps the driving semiconductor layer 130a.

The thin film switching transistor T2 includes the switching semiconductor layer 130b, the switching gate electrode G2, the switching source electrode S2, and the switching drain electrode D2. The switching gate electrode G2 is electrically connected to the scan line 121 formed with a different layer. The switching gate electrode G2 and the scan line 121 are electrically connected through a first connecting member 41, formed with the same layer as the data line 171. The switching gate electrode G2 and the scan line 121 are connected to the first connecting member 41 through contact holes 62 and 63.

The switching source electrode S2, as a portion of the data line 171, is connected to a switching source region 133b doped with the impurity in the switching semiconductor layer 130b. The switching drain electrode D2 corresponds to a switching drain region 135b doped with the impurity in the switching semiconductor layer 131b. The switching semiconductor, positioned between the switching source region 133b and the switching drain region 135b, becomes the switching channel region 131b.

The thin film compensation transistor T3 includes the compensation semiconductor layer 130c, the compensation gate electrode G3, the compensation source electrode S3, and the compensation drain electrode D3. The compensation source electrode S3 corresponds to a compensation source region 133c doped with the impurity in the compensation semiconductor layer 131c. The compensation drain electrode D3 corresponds to a compensation drain region 135c doped with the impurity. Also, the compensation semiconductor layer, positioned between the compensation source region 133c and the compensation drain region 135c, becomes a compensation channel region 131c.

The compensation gate electrode G3 is electrically connected to the scan line 121 formed with a different layer. The compensation gate electrode G3 and the scan line 121 are connected through a second connecting member 42, formed with the same layer as the data line 171. The compensation gate electrode G3 and the scan line 121 are connected to the second connecting member 42 through contact holes 74 and 75.

The initialization transistor T4 includes the initialization semiconductor layer 130d, the initialization gate electrode G4, the initialization source electrode S4, and the initialization drain electrode D4. The initialization source electrode S4 corresponds to an initialization source region 133d doped with the impurity. The initialization drain electrode D4 corresponds to an initialization drain region 135d doped with the impurity.

Also, the initialization semiconductor layer, positioned between the initialization source region 133d and the initialization drain region 135d, becomes an initialization channel region 131d. The initialization transistor T4 may be disposed in a pair to be symmetrical with respect to the previous scan line 122. The initialization semiconductor layer 130d includes a heavily doped region 133 sharing the source region and the drain region of each transistor.

The initialization gate electrode G4 is electrically connected to the previous scan line 122 formed with a different layer. The initialization gate electrode G4 and the previous scan line 122 are connected through a third connecting member 43, formed with the same layer as the data line 171. The initialization gate electrode G4 and the previous scan line 122 are connected to the third connecting member 43 through contact holes 76 and 77.

The operation control transistor T5 includes the operation control semiconductor layer 130e, the operation control gate electrode G5, the operation control source electrode S5, and the operation control drain electrode D5. The operation control source electrode S5 as a portion of the driving voltage line 172 is connected to an operation control source region 133e doped with the impurity in the operation control semiconductor layer 130e. The operation control drain electrode D5 corresponds to an operation control drain region 135e doped with the impurity in the operation control semiconductor layer 130e. Also, the operation control semiconductor layer, positioned between the operation control source region 133e and the operation control drain region 135e, becomes an operation control channel region 131e.

The operation control gate electrode G5 is electrically connected to the emission control line 123 formed with a different layer. The operation control gate electrode G5 and the emission control line 123 formed with the same layer as the data line 171 are connected through the fourth connecting member 44. The operation control gate electrode G5 and the emission control line 123 are connected to a fourth connecting member 44 through contact holes 71 and 72.

The emission control transistor T6 includes the emission control semiconductor layer 130f, the emission control gate electrode G6, the emission control source electrode S6, and the emission control drain electrode D6. The emission control source electrode S6 corresponds to an emission control source region 133f doped with the impurity in the emission control semiconductor layer 130f The emission control drain electrode D6 is connected to an emission control drain region 135f doped with the impurity. Also, the emission control semiconductor layer, positioned between the emission control source region 133f and the emission control drain region 135f, becomes an emission control channel region 131f.

The emission control gate electrode G6 is electrically connected to the emission control line 123 formed with a different layer. The emission control gate electrode G6 and the emission control line 123, which are formed with the same layer as the data line 171, are connected through a fifth connecting member 45. The emission control gate electrode G6 and the emission control line 123 are connected to the fifth connecting member 45 through contact holes 67 and 68.

The bypass thin film transistor T7 includes the bypass semiconductor layer 130g, the bypass gate electrode G7, the bypass source electrode S7, and the bypass drain electrode D7. The bypass source electrode S7 corresponds to a bypass source region 133g doped with the impurity in the bypass semiconductor layer 130g. The bypass drain electrode D7 corresponds to a bypass drain region 135g doped with the impurity in the bypass semiconductor layer 130g. Also, the bypass semiconductor layer, which is positioned between the bypass source region 133g and the bypass drain region 135g, becomes a bypass channel region 131g.

The bypass gate electrode G7 is electrically connected to the bypass control line 128 formed with a different layer. The bypass gate electrode G7 and the bypass control line 128 are formed with the same layer as the data line 171, and are connected through a sixth connecting member 46. The bypass gate electrode G7 and the bypass control line 128 are connected to the sixth connecting member 46 through contact holes 81 and 82.

One end of the driving semiconductor layer 130a of the driving transistor T1 is connected to the switching semiconductor layer 130b and the operation control semiconductor layer 130e. Anther end of the driving semiconductor layer 130a is connected to the compensation semiconductor layer 130c and the emission control semiconductor layer 130f. Accordingly, the driving source electrode S1 is connected to the switching drain electrode D2 and the operation control drain electrode D5. The driving drain electrode D1 is connected to the compensation source electrode S3 and the emission control source electrode S6.

The storage capacitor Cst includes the first storage capacitor plate Cst1 and the second storage capacitor plate Cst2, with the second gate insulating layer 142 between the plates Cst1 and Cst2. The first storage capacitor plate Cst1 is the driving gate electrode G1, the second gate insulating layer 142 is the dielectric material, and the second storage capacitor plate Cst2 is a portion of a separate signal line 126. The storage capacitance is determined by the charge stored in the storage capacitor Cst and the voltage between the two capacitor plates.

A seventh connecting member 174 is at the same layer as and parallel to the data line 171, and connects the driving gate electrode G1 and the compensation drain region 135c, that is the compensation drain electrode D3 of the compensation thin film transistor T3, to each other. The first storage capacitor plate Cst1 corresponds to the driving gate electrode G1, such that the first storage capacitor plate Cst1 is connected to a connecting member 174 through a contact hole 65 and the compensation drain electrode D3 is connected to the connecting member 174 through the contact hole 73. Accordingly, the storage capacitor Cst has a storage capacitance based on a difference between the driving voltage ELVDD (transmitted to the second storage capacitor plate Cst2 from the driving voltage line 172 through contact holes 64 and 66) and the gate voltage of the driving gate electrode G1.

The switching thin film transistor T2 is used as a switch for selecting the pixel to emit light. The switching gate electrode G2 is connected to the scan line 121, the switching source electrode S2 is connected to the data line 171, and the switching drain electrode D2 is connected to the thin film driving transistor T1 and the thin film operation control transistor T5. Also, the emission control drain electrode D6 of the emission control transistor T6 is directly connected to a first electrode 191 as the anode of the organic emission diode 70.

FIGS. 4 and 5 illustrate an embodiment of the organic light emitting diode display in a laminating order. The structure of operation control thin film transistor T5 may be similar to the laminating structure of the emission control thin film transistor T6.

Referring to FIGS. 4 and 5, the substrate 100 is or includes an insulation substrate made of, for example, glass, quartz, ceramic, or plastic. A buffer layer 110 is formed on a substrate 100.

The driving semiconductor layer 130a, the switching semiconductor layer 130b, the compensation semiconductor layer 130c, the initialization semiconductor layer 130d, the operation control semiconductor layer, the emission control semiconductor layer 130f, and the bypass semiconductor layer 130g are formed on the buffer layer 110.

The driving semiconductor layer 130a includes the driving source region 133a and the driving drain region 135a, which face each other, with the driving channel region 131a therebetween. The switching semiconductor layer 130b includes the switching source region 133b and the switching drain region 135b, which face each other, with the switching channel region 131b therebetween. Also, the compensation semiconductor layer 130c includes the compensation channel region 131c, the compensation source region 133c, and the compensation drain region 135c. The initialization semiconductor layer 130d includes the initialization channel region 131d, the initialization source region 133d, and the initialization drain region 135d. The emission control semiconductor layer 130f includes the emission control channel region 131f, the emission control source region 133f, and the emission control drain region 135f. The bypass semiconductor layer 130g includes the bypass channel region 131g, the bypass source region 133g, and the bypass drain region 135g.

A first gate insulating layer 140 is on the driving channel region 131a, the switching channel region 131b, the compensation channel region 131c, the initialization channel region 131d, the emission control channel region 131f, and the bypass channel region 131g.

The driving channel region 131a, the switching channel region 131b, the compensation channel region 131c, the initialization channel region 131d, the emission control channel region 131f, and the bypass channel region 131g, and the first gate insulating layer 140, may have the same shape, e.g., a plane shape.

The first gate insulating layer 140 includes, for example, silicon nitride (SiNₓ) or a silicon oxide (SiOₓ).

The driving gate electrode G1, the switching gate electrode G2, the compensation gate electrode G3, the initialization gate electrode G4, the emission control gate electrode G6, and the bypass gate electrode G7 are formed on the first gate insulating layer 140.

The driving gate electrode G1, the switching gate electrode G2, the compensation gate electrode G3, the initialization gate electrode G4, the emission control gate electrode G6, and the bypass gate electrode G7 may have the same shape as the first gate insulating layer 140, e.g., a plane shape. Edges of the driving gate electrode G1, the switching gate electrode G2, the compensation gate electrode G3, the initialization gate electrode G4, the emission control gate electrode G6, and the bypass gate electrode G7, and the edge of the first gate insulating layer 140, may at least partially overlap.

A second gate insulating layer 142 is formed on the substrate including the gate electrodes G1 to G7. The second gate insulating layer 142 may be formed, for example, of the same material as the first gate insulating layer 140.

The scan line 121, the previous scan line 122, the emission control line 123, the signal line 126 for the storage capacitor plate, and the bypass control line 128 are formed on the second gate insulating layer 142.

An interlayer insulating layer 160 is formed on the gate wires 121, 122, 123, 126, and 128. The interlayer insulating layer 160 may be formed, for example, using a ceramic-based material such as a silicon nitride (SiNₓ) or a silicon oxide (SiOₓ).

The data line including the switching source electrode S2, the driving voltage line 172, the first connecting member 41, the second connecting member 42, the third connecting member 43, the fourth connecting member 44, the fifth connecting member 45, the sixth connecting member 46, the seventh connecting member 174, the eighth connecting member 48, and the emission control drain electrode D6 are formed on the interlayer insulating layer 160.

The switching source electrode S2 is connected to the switching source region 133b through a contact hole 61 formed in the interlayer insulating layer 160. The emission control drain electrode D6 is connected to the emission control drain region 135f through a contact hole 69 formed in the interlayer insulating layer 160 and the second gate insulating layer 142.

The first connecting member 41 connects the switching gate electrode G2 and the scan line 121 through the contact hole 62 formed in the interlayer insulating layer 160 and the second gate insulating layer 142 and the contact hole 63 formed in the interlayer insulating layer 160. The fifth connecting member 45 connects the emission control line 123 and the operation control gate electrode G5 though the contact hole 67 formed in the interlayer insulating layer 160 and the contact hole 68 in the interlayer insulating layer 160 and the second gate insulating layer 142.

The seventh connecting member 174 connects the second storage capacitor plate Cst2 and the driving gate electrode G1 through the contact hole 66 in the interlayer insulating layer 160 and the contact hole 65 in the interlayer insulating layer 160 and the second gate insulating layer 142.

The eighth connecting member 48 is connected to the initialization semiconductor layer 130d and the bypass semiconductor layer 130g through a contact hole 83 in the interlayer insulating layer 160, and is connected to a semiconductor layer 137 doped with the conductive impurity of the high concentration.

A passivation layer 180 is formed on the data line 171 including the switching source electrode S2, the driving voltage line 172, the first connecting member 41, the second connecting member 42, the third connecting member 43, the fourth connecting member 44, the fifth connecting member 45, the sixth connecting member 46, the seventh connecting member 174, the eighth connecting member 48, and the emission control drain electrode D6.

The first electrode 191 and the initialization voltage line 124 are formed on the passivation layer 180. The first electrode 191 is connected to the emission control drain electrode D6 through a contact hole 85 formed in the passivation layer 180. The initialization voltage line 124 is connected to the eighth connecting member 48 through a contact hole 87 formed in the passivation layer 180.

A pixel definition layer 350 is formed on the edge of the first electrode 191 and the passivation layer 180. The pixel definition layer 350 has an opening 351 exposing the first electrode 191. The pixel defining layer 190 may include, for example, a polyacrylate resin, a polyimide resin, or a silica-based inorganic material.

An organic emission layer 370 is formed on the first electrode 191 exposed through the opening 351. A second electrode 270 is formed on the organic emission layer 370. The organic light emitting diode 70 including the first electrode 191, the organic emission layer 370, and the second electrode 270 may be formed as described above.

The first electrode 191 may be an anode serving as a hole injection electrode, and the second electrode 270 may be a cathode serving as an electron injection electrode. In another embodiment, depending on a driving method of the organic light emitting display, the first electrode 191 may be the cathode and the second electrode 270 may be the anode. In operation, holes and electrons are injected into the organic emission layer 370 from the pixel electrode 191 and the common electrode 270, respectively. Exitons are generated based on coupling of the injected holes and electrons. When the exitons fall from an excited state to a ground state, light is emitted.

The organic emission layer 370 may include a low-molecular organic material or high-molecular organic material, e.g., poly(3,4-ethylenedioxythiophene) (PEDOT). Further, the organic emission layer 370 may be formed as a multilayer including an emission layer, and one or more of a hole injection layer (HIL), a hole transporting layer (HTL), an electron transporting layer (ETL), or an electron injection layer (EIL). When the organic emission layer 370 includes all of the aforementioned layers, the hole injection layer (HIL) is disposed on a pixel electrode which serves as an anode, and the hole transporting layer (HTL), the emission layer, the electron transporting layer (ETL), the electron injection layer (EIL) may be sequentially laminated thereon.

The organic emission layer 370 may include a red organic emission layer to emit red light, a green organic emission layer to emit green light, and a blue organic emission layer to emit blue light. The red organic emission layer, the green organic emission layer, and the blue organic emission layer are included in a red pixel, a green pixel, and a blue pixel, respectively, to thereby generate a color image.

The organic emission layer 370 may implement the color image, for example, by laminating the red organic emission layer, the green organic emission layer, and the blue organic emission layer together in the red pixel, the green pixel, and the blue pixel. In another embodiment, white organic emission layers emitting white light are formed in the red, green, and blue pixels, and a red color filter, a green color filter, and a blue color filter are respectively included in each pixel. In this latter embodiment, a deposition mask for depositing the red organic emission layer, the green organic emission layer, and the blue organic emission layer on respective pixels (e.g., the red pixel, the green pixel, and the blue pixel) may not be used.

In another embodiment, the white organic emission layer may be formed by one organic emission layer, and may include a configuration in which a plurality of organic emission layers are laminated to emit white light. For example, the white organic emission layer may emit white light by combining at least one yellow organic emission layer and at least one blue organic emission layer, may emit white light by combining at least one cyan organic emission layer and at least one red organic emission layer, and/or may emit white light by combining at least one magenta organic emission layer and at least one green organic emission layer.

An encapsulation member protecting the organic light emitting diode 70 may be formed on the common electrode 270. The encapsulation member may be encapsulated on the substrate 100 by a sealant, and may be made of various materials such as glass, quartz, ceramic, plastic, or metal. A thin film encapsulation layer may be formed by depositing an inorganic layer and an organic layer on the common electrode 270 without using a sealant.

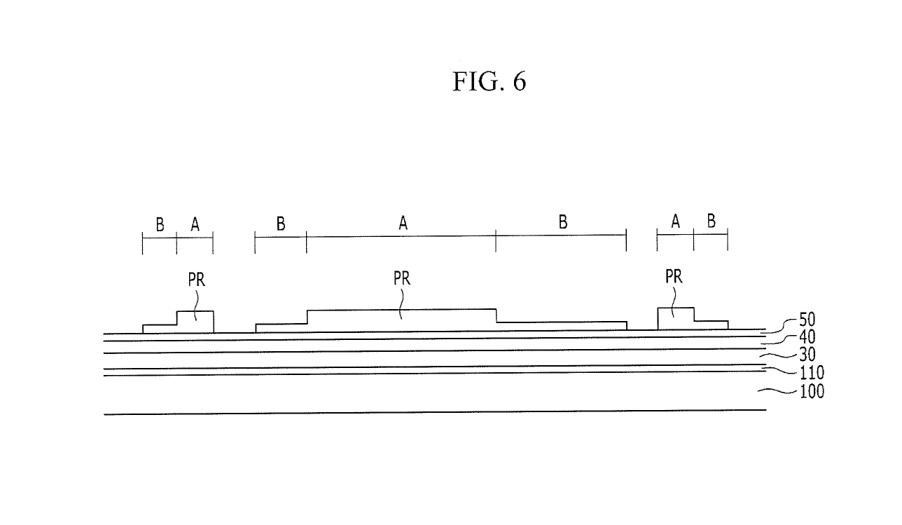

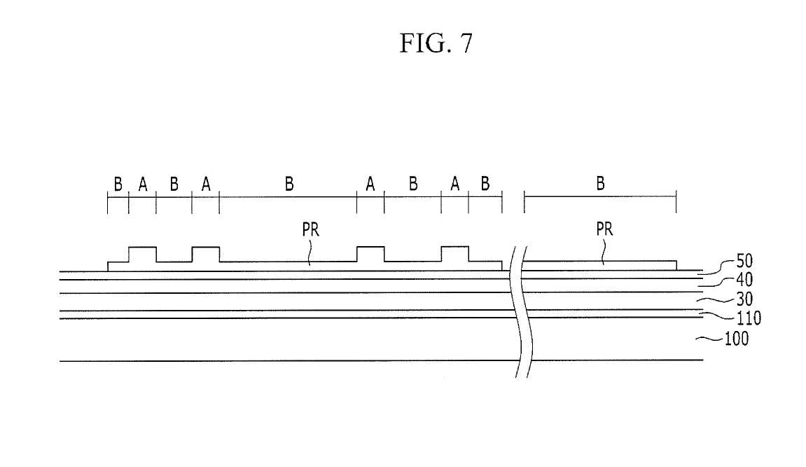

FIGS. 6 and 7 illustrate an embodiment of a method for manufacturing an organic light emitting device, which, for example, may be the device in FIG. 2 to FIG. 5.

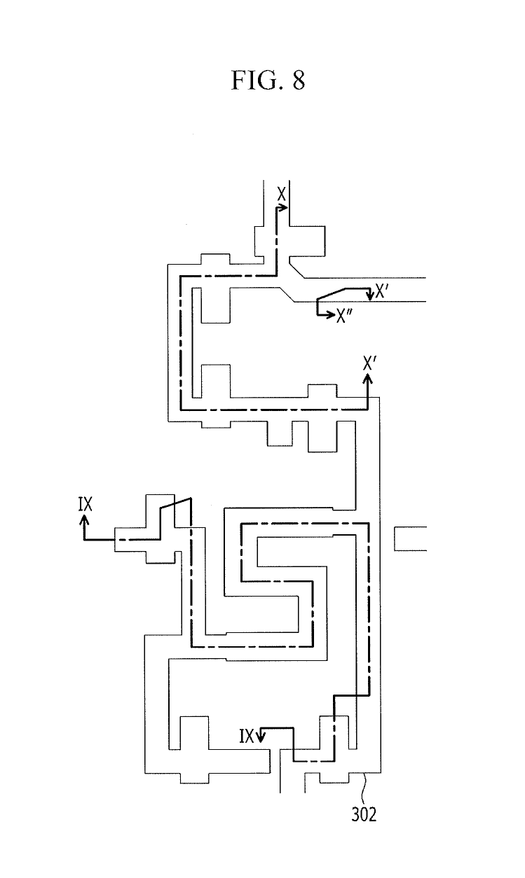

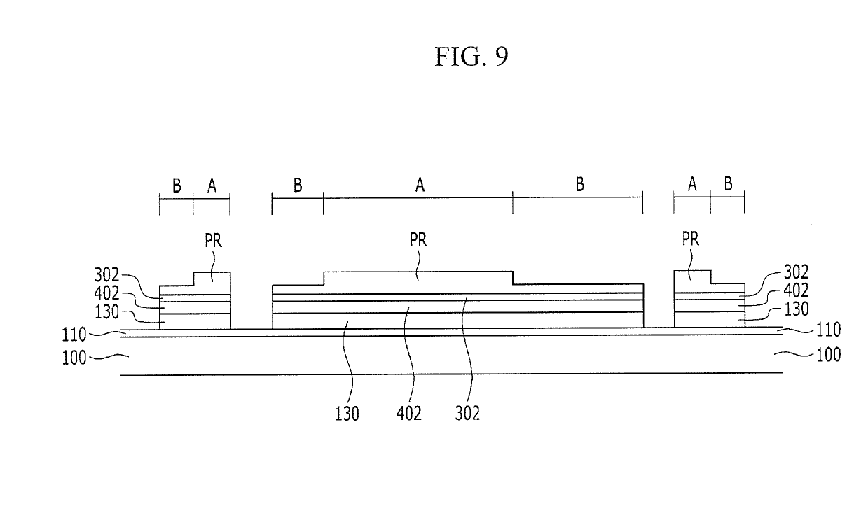

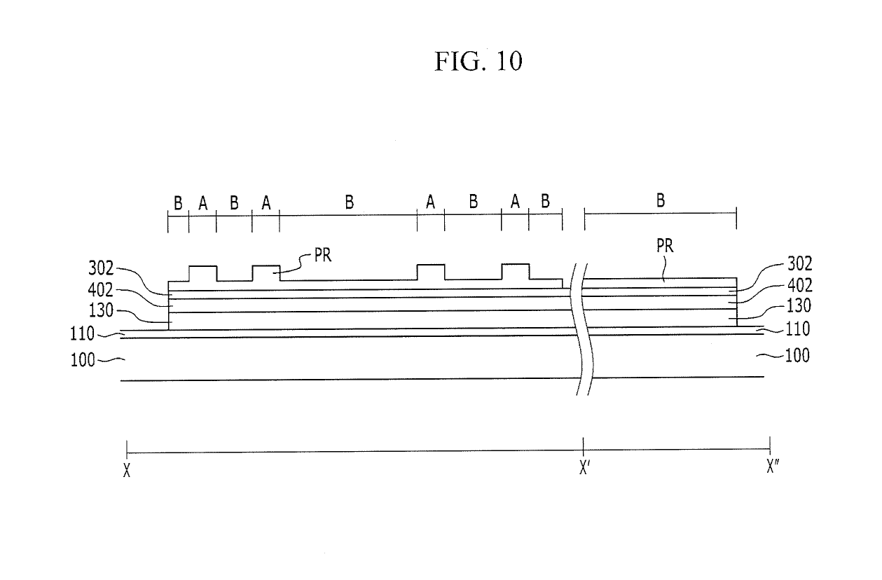

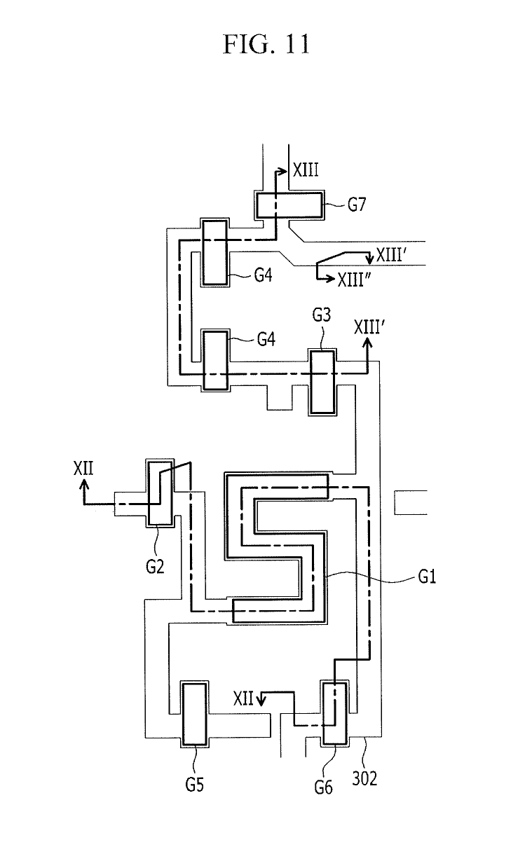

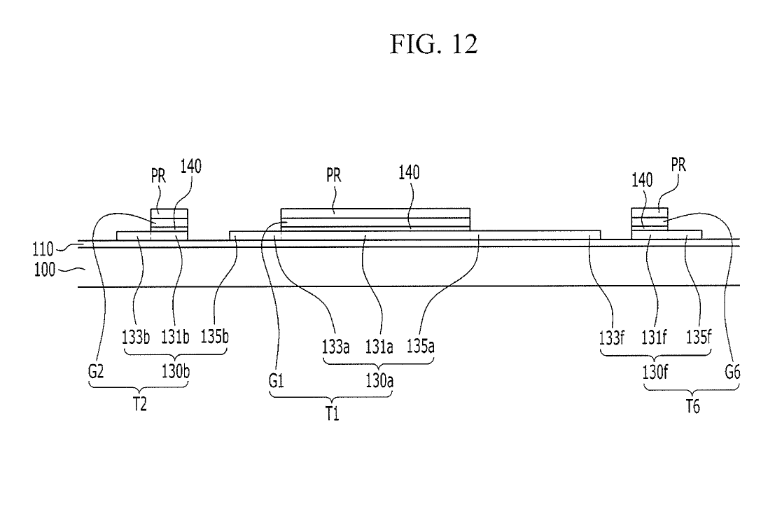

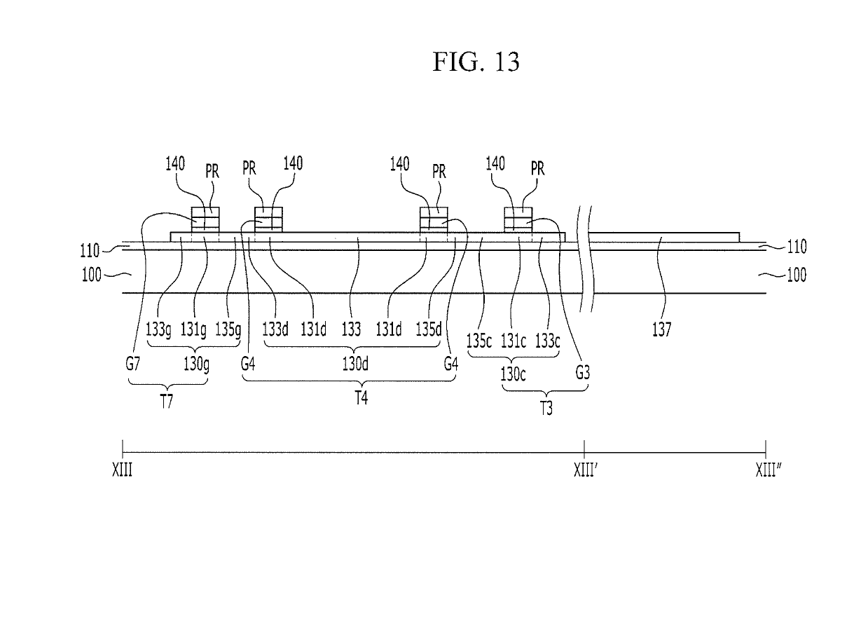

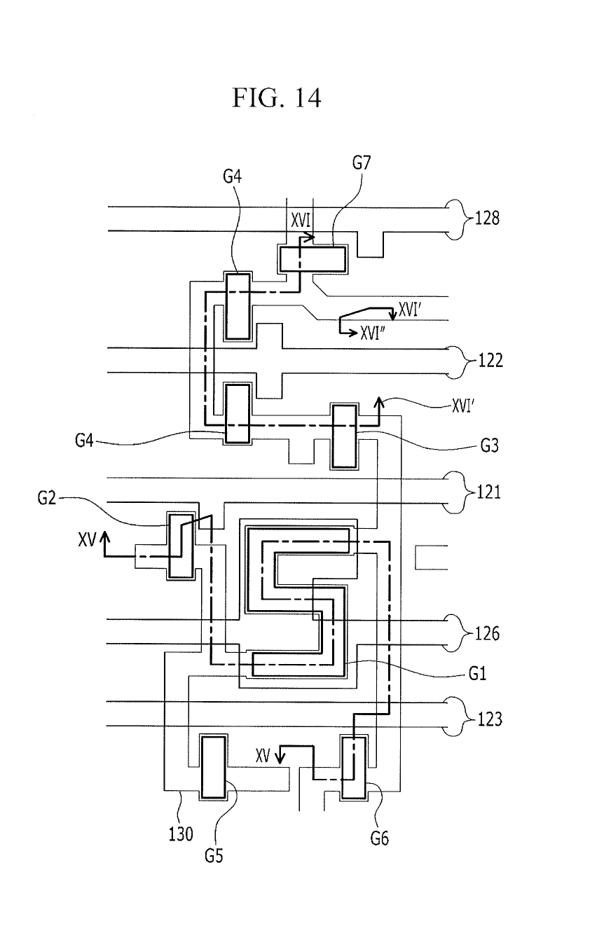

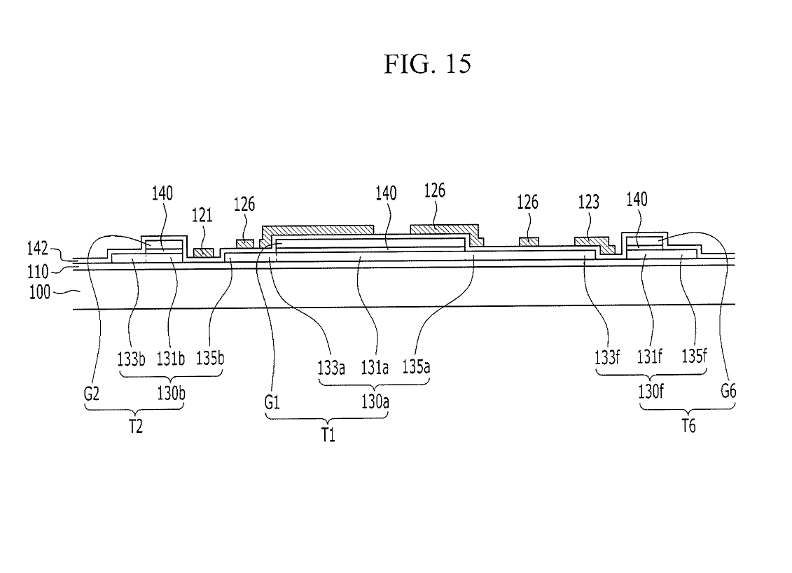

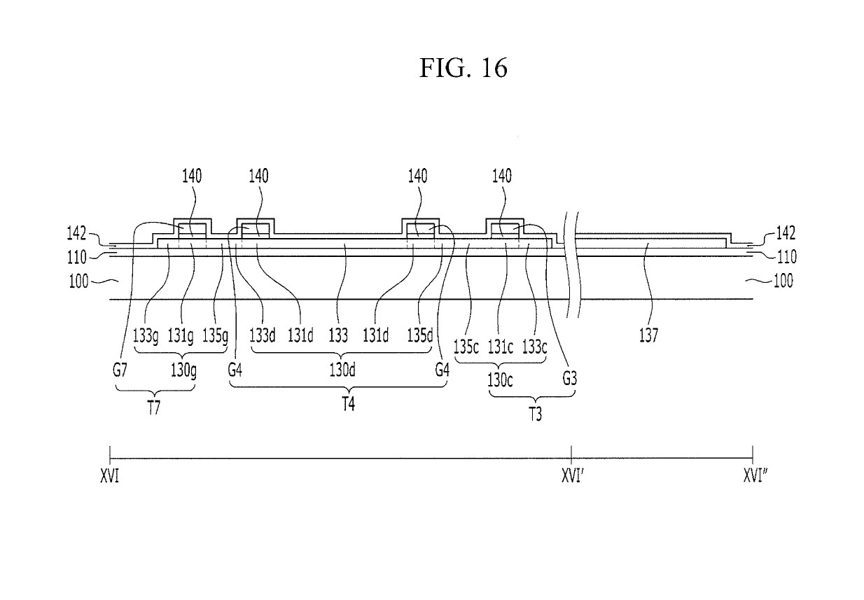

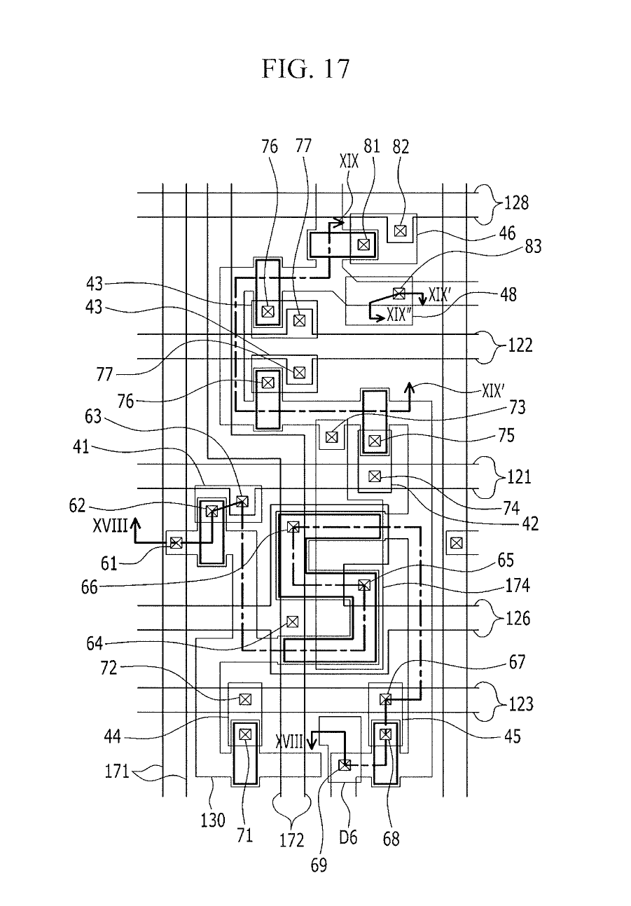

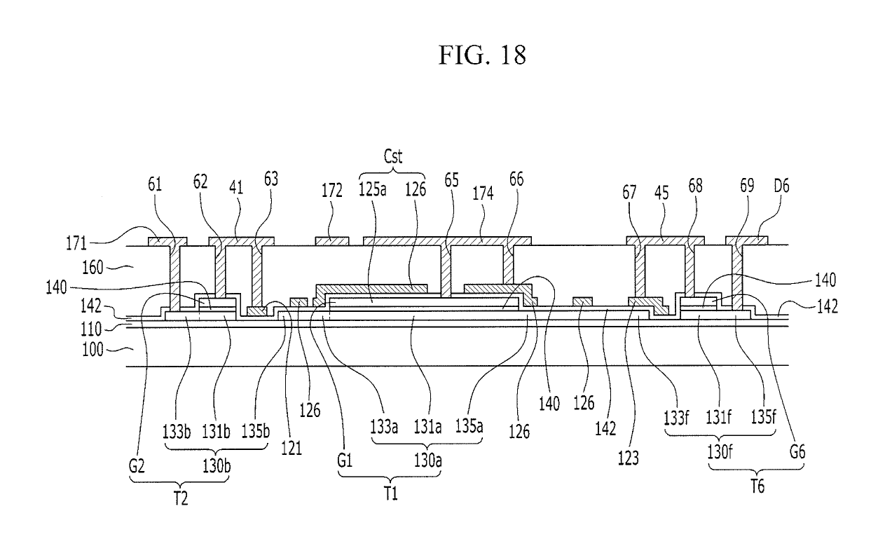

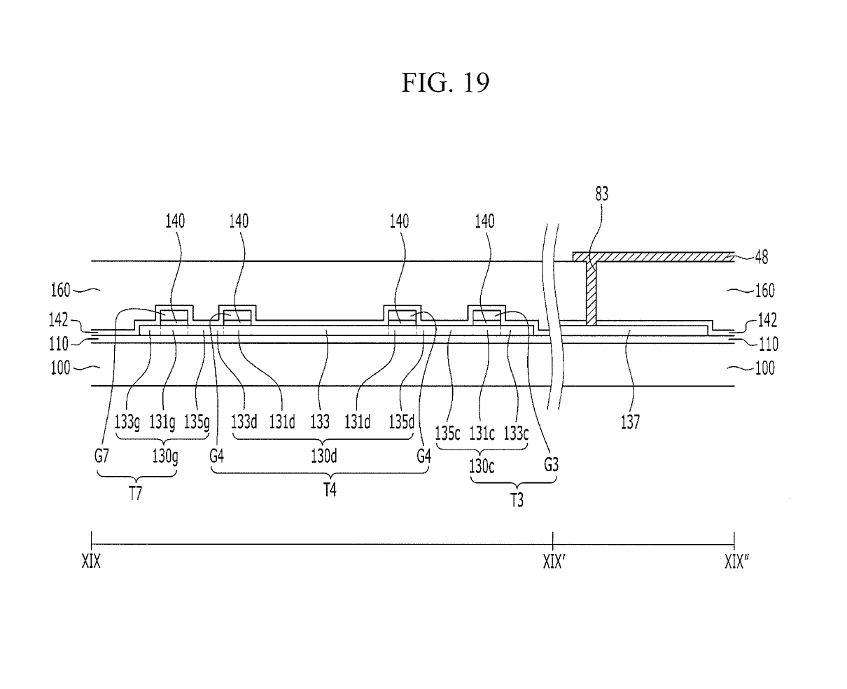

More specifically, FIGS. 6 and 7 illustrate cross-sectional views of operations of the method. FIG. 8 illustrates a layout view of an operation following the operation(s) of FIGS. 6 and 7. FIG. 9 illustrates a cross-sectional view taken along a line IX-IX in FIG. 8. FIG. 10 illustrates a cross-sectional view taken along lines X-X′ and X′-X″ in FIG. 8. FIG. 11 illustrates a layout view of an operation following the operation in FIG. 8. FIG. 12 illustrates a cross-sectional view taken along a line XII-XII in FIG. 11. FIG. 13 illustrates a cross-sectional view taken along lines XIII-XIII′ and XIII′-XIII″ in FIG. 11. FIG. 14 illustrates a layout view of an operation following the operation of FIG. 11, FIG. 15 illustrates a cross-sectional view taken along a line XV-XV in FIG. 14. FIG. 16 illustrates a cross-sectional view taken along lines XVI-XVI′ and XVI′-XVI″ in FIG. 14. FIG. 17 illustrates a layout view of an operation following the operation of FIG. 14. FIG. 18 illustrates a cross-sectional view taken along a line XVIII-XVIII in FIG. 17. FIG. 19 illustrates a cross-sectional view taken along lines XIX-XIX′ and XIX′-XIX″ in FIG. 17.

First, as shown in FIGS. 6 and 7, the buffer layer 110 is formed on the substrate 100. The buffer layer 110 may include, for example, a silicon nitride or a silicon oxide.

Next, a polysilicon layer 30 is formed by forming and crystallizing an amorphous silicon layer on the buffer layer 110, and an insulating layer 40 and a metal layer 50 are deposited on the polysilicon layer 30.

The insulating layer 40 may be made of a silicon nitride or a silicon oxide. The metal layer 50 is formed, for example, by stacking W, Cu, Al, or alloys thereof, in a single layer or a plurality of layers.

Thereafter, a photosensitive film pattern PR having different thicknesses is formed by applying, exposing, and developing a photosensitive material on the metal layer 50. The photosensitive film pattern includes an electrode portion corresponding to a metal layer, an insulating layer, and a polysilicon layer of an electrode area A in which a gate electrode is to be formed, and the remaining portion corresponding to the remaining area B, excluding for the electrode portion.

In the photosensitive film pattern PR, a photosensitive film pattern PR at an electrode area A has a greater thickness than a photosensitive film pattern at the remaining area B.

Various methods may be used to form the different thicknesses of the photosensitive film pattern. A method of forming a transparent area, a light blocking area, and a semi-transparent area in an exposure mask is an example. In the semi-transparent area, a thin film having a slit pattern, a lattice pattern, or intermediate transmittance, or an intermediate thickness, is provided. When the slit pattern is used, a width of a slit or a gap between slits may be smaller than a resolution of an exposer used in a photolithography process. Another example is to use a photosensitive film in which reflow is possible. That is, after forming a photosensitive pattern film in which reflow is possible with a common mask having only a transparent area and a light blocking area, a thin portion is formed by enabling the photosensitive film to flow to an area in which a photosensitive film does not remain.

Next, as illustrated in FIGS. 8 to 10, the metal layer 50, the insulating layer 40, and the polysilicon layer 30 are etched using the photosensitive film pattern PR as a mask. A metal pattern 302, an insulating layer pattern 402, and a semiconductor layer 130 are formed by this etching operation.

The metal layer is etched, for example, by wet etching. The insulating layer and the polysilicon layer are etched, for example, by dry etching. The metal layer may be formed in a single layer, or a plurality of layers including Ti or Al that can undergo dry etching. The metal layer, the insulating layer, and the polysilicon layer may be etched at one time by dry etching.

Next, as shown in FIGS. 11 to 13, the remaining portion B of the photosensitive film pattern is removed, for example, by an etching back operation. The electrode portion A is partially removed, and thus the thickness and width of the photosensitive film pattern PR is decreased.

Thereafter, the gate electrodes G1, G2, G3, G4, G5, and G6 are formed by etching the metal pattern using the electrode portion A as a mask.

Also, the exposed semiconductor 130 is doped with the conductive impurity using the photosensitive film pattern at the electrode region A as a mask, to form the source regions 133a, 133b, 133c, 133d, 133e, 133f, and 133g and the drain regions 135a, 135b, 135c, 135d, 135e, 135f, and 135g.

The photosensitive film pattern positioned at the electrode region A may have a width that is reduced when removing the photosensitive film pattern at the remaining region B. In one embodiment, the width of the photosensitive film pattern positioned at the electrode region A is wider than the gate electrode to be formed by the width that the photosensitive film pattern is reduced.

Next, as shown in FIGS. 14 to 16, after removing the photosensitive film pattern remaining in the electrode region A, the second gate insulating layer 142 is formed on the gate electrodes G1 to G7.

Next, a metal layer is formed and patterned on the second gate insulating layer 142 to form the scan line 121, the previous scan line 122, and the emission control line 123. In this case, the metal layer may include, for example, the same material as the gate electrodes G1 to G7.

Next, as shown in FIGS. 17 to 19, the interlayer insulating layer 160 having the contact holes 61, 62, 63, 64, 65, 66, 67, 68, 69, 81, 82, and 83 is formed on the scan line 121, the previous scan line 122, and the emission control line 123. The data line 171, the driving voltage line 172, the first connecting member 41, the second connecting member 42, the third connecting member 43, the fourth connecting member 44, the fifth connecting member 45, the sixth connecting member 46, the seventh connecting member 174, and the eighth connecting member 48 are formed on the interlayer insulating layer 160.

Next, as shown in FIGS. 3 to 5, a passivation layer 180 is formed on the data line 171 and the driving voltage line 172. The connecting members 41 to 46, 48, and 174 and the contact holes 85 and 87 are formed to expose the emission control drain electrode D6 and the eighth connecting member 48.

Next, a metal layer is formed and patterned on the passivation layer 180 to form the first electrode 191 and the initialization voltage line 124 connected to the emission control drain electrode D6 and the eighth connecting member 48 through the contact holes 85 and 87.

Next, the pixel definition layer 350 having the opening 351 exposing the first electrode 191 is formed on the first electrode 191 and the initialization voltage line 124. Next, the organic emission layer 370 is formed in the opening 351 of the pixel definition layer 350 and the second electrode 270 is formed on the organic emission layer 370.

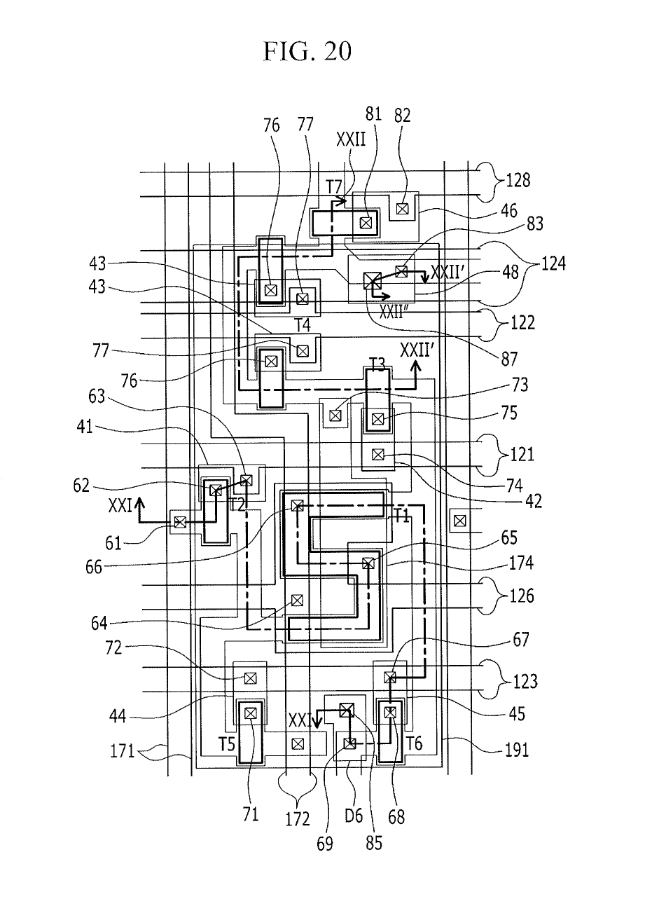

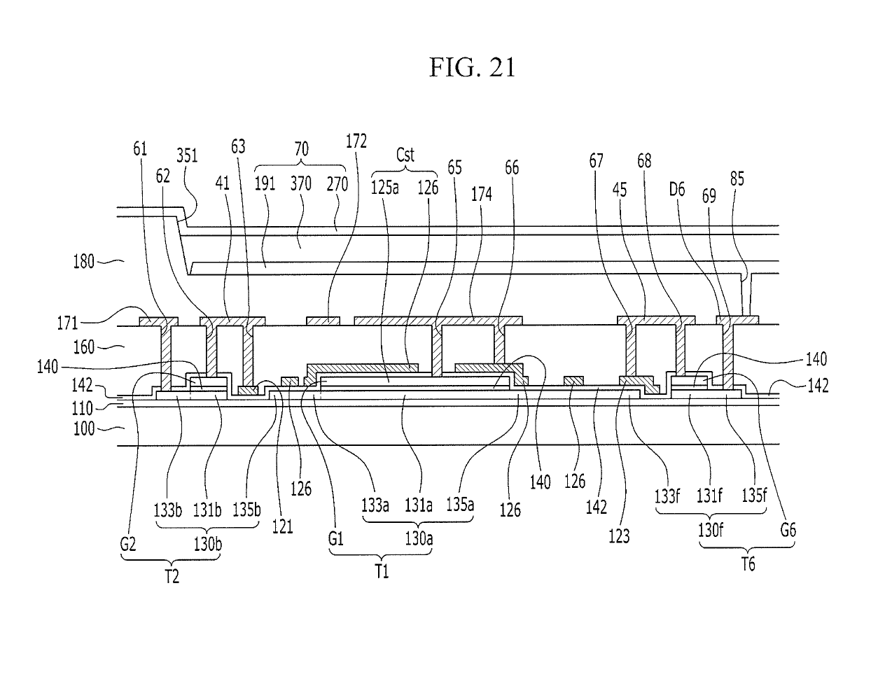

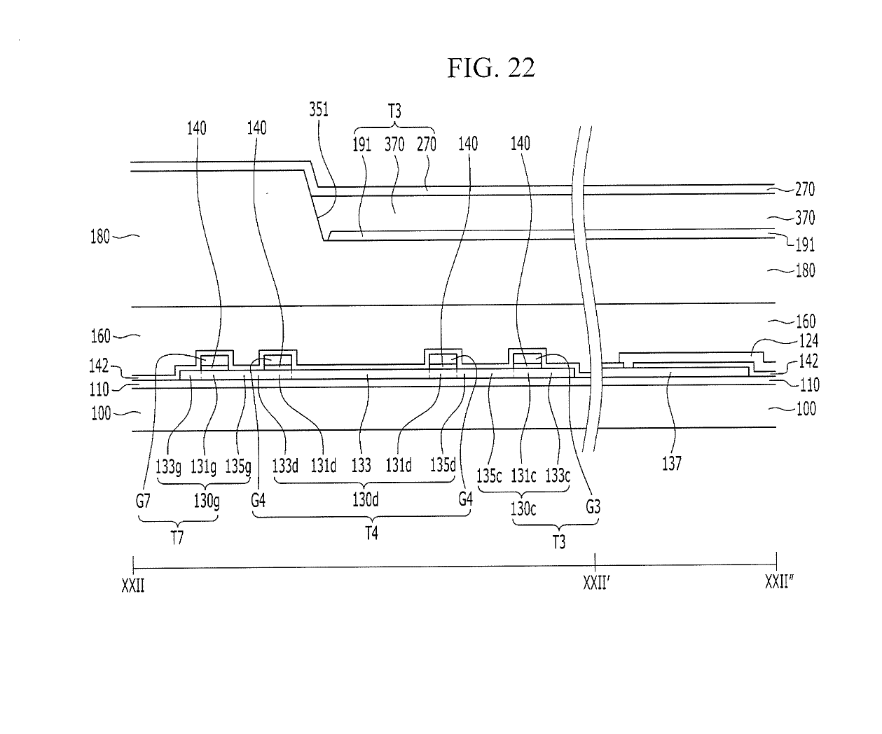

FIG. 20 illustrates another embodiment of an organic light emitting display device. FIG. 21 illustrates a cross-sectional view taken along a line XXI-XXI in FIG. 20. FIG. 22 illustrates a cross-sectional view taken along lines XXII-XXII′ and XXII′-XXII″ in FIG. 20. The interlayer configuration may be the same as in the organic light emitting device of FIGS. 2 to 5, except for the following differences.

The organic light emitting device includes the substrate 100, the buffer layer 110 formed on the substrate 100, and the semiconductor layer 130 formed on the buffer layer 110 and including the driving semiconductor layer 130a, the switching semiconductor layer 130b, the compensation semiconductor layer 130c, the initialization semiconductor layer 130d, the operation control semiconductor layer 130e, the emission control semiconductor layer 130f, and the bypass semiconductor layer 130g.

Also, the driving gate electrode G1, the switching gate electrode G2, the compensation gate electrode G3, the initialization gate electrode G4, the emission control gate electrode G6, and the bypass gate electrode G7 overlapping the channel regions 131a, 131b, 131c, 131d, 133e, 133f, and 133g are formed on the semiconductor layer 130.

The first gate insulating layer 140 is positioned between the gate electrodes G1 to G7 and the channel regions 131a, 131b, 131c, 131d, 133e, 133f, and 133g, and may have the same plane shape as the gate electrodes G1 to G7 and the channel regions 131a, 131b, 131c, 131d, 133e, 133f, and 133g.

The second gate insulating layer 142 is formed on the gate electrodes G1 to G7. The second gate insulating layer 142 includes a contact hole 89 exposing the semiconductor layer 137 connected to the bypass semiconductor layer 130g and doped with the conductive impurity of the high concentration.

The scan line 121, the previous scan line 122, the emission control line 123, the storage capacitor plate signal line 126, the bypass control line 128, and the initialization voltage line 124 are formed on the second gate insulating layer 142. The initialization voltage line 124 is connected to the semiconductor layer 137 through the contact hole 89.

The interlayer insulating layer 160, having the contact holes 61, 62, 63, 64, 65, 66, 67, 68, 69, 81, and 82, is formed on the scan line 121, the previous scan line 122, the emission control line 123, the storage capacitor plate signal line 126, the bypass control line 128, and the initialization voltage line 124.

The data line 171 including the switching source electrode S2, the driving voltage line 172, the first connecting member 41, the second connecting member 42, the third connecting member 43, the fourth connecting member 44, the fifth connecting member 45, the sixth connecting member 46, the seventh connecting member 174, and the emission control drain electrode D6 are formed on the interlayer insulating layer 160.

The passivation layer 180, including the contact hole 85 and the opening 351, is formed on the data line 171 including the switching source electrode S2, the driving voltage line 172, the first connecting member 41, the second connecting member 42, the third connecting member 43, the fourth connecting member 44, the fifth connecting member 45, the sixth connecting member 46, the seventh connecting member 174, and the emission control drain electrode D6.

The first electrode 191 is formed in the opening 351. The first electrode 191 is connected to the emission control drain electrode D6 through the contact hole 85.

The passivation layer 180 is formed to have the opening 351 so that a separate pixel definition layer may not be formed. Unlike the embodiment of FIGS. 4 and 5, the first electrode 191 is formed after forming the opening 351 such that the boundary line of the first electrode 191 is positioned in the boundary line of the opening 351. That is, in the embodiment of FIG. 4 and FIG. 5, the opening 351 is formed after forming the first electrode 191 such that the boundary line of the first electrode 191 is covered by the pixel definition layer such that the boundary line of the opening 351 is positioned in the boundary line of the first electrode 191.

Also, unlike the embodiment of FIGS. 4 and 5, the initialization voltage line 124 is formed on the second gate insulating layer 142 like the scan line 121. As a result, the eighth connecting member may be omitted.

Also, the initialization voltage line 124 of FIGS. 4 and 5 is formed with the same layer as the first electrode 191. As a result, the first electrode 191 and the initialization voltage line 124 are formed with a predetermined interval to not be short-circuited. However, in the embodiment of FIGS. 20 to 22, the scan line 121 and the initialization voltage line 124 are at the same layer. As a result, the first electrode 191 may be formed to extend to the region in which the initialization voltage line 124 of FIGS. 4 and 5 is formed.

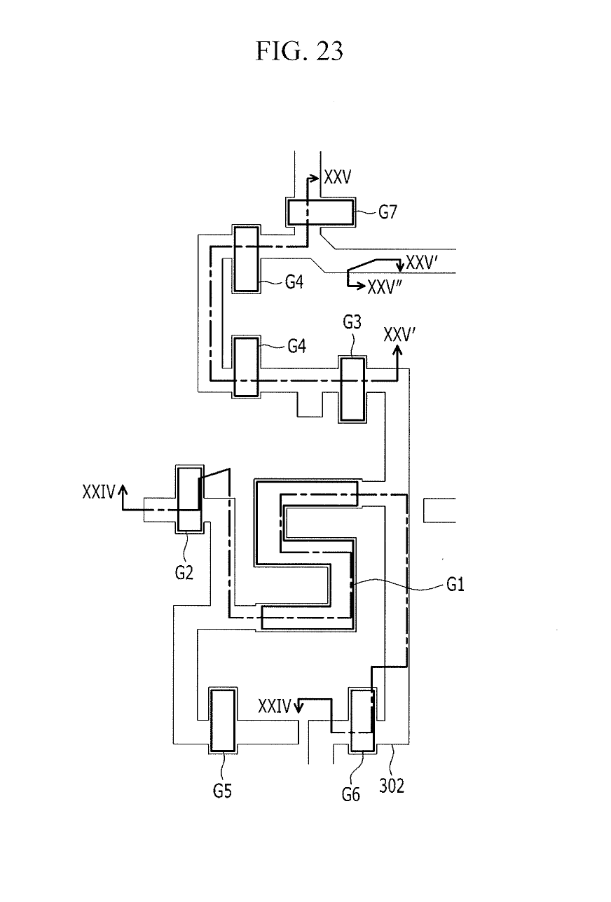

FIGS. 23 to 30 illustrate another embodiment of a method for manufacturing an organic light emitting device, which, for example, may be the device of FIGS. 20 to 22.

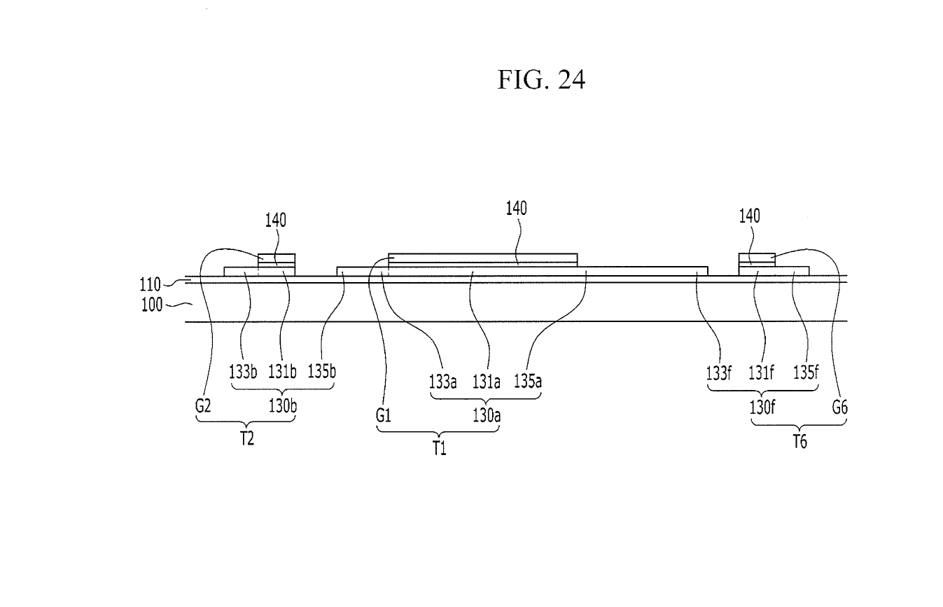

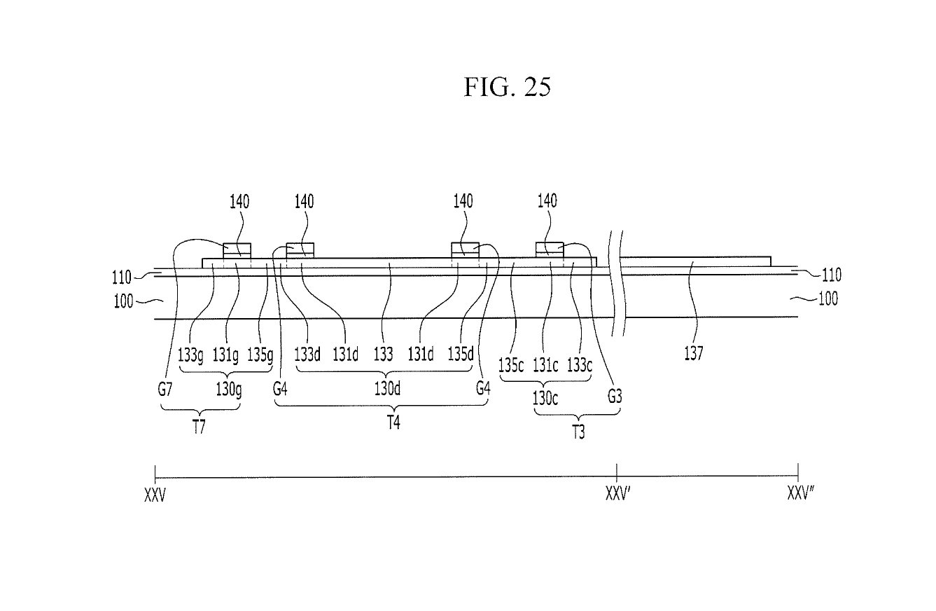

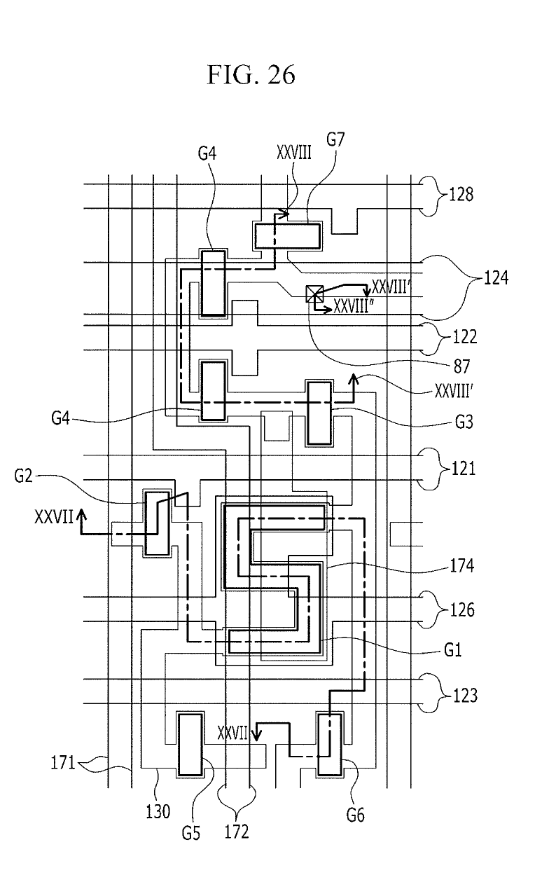

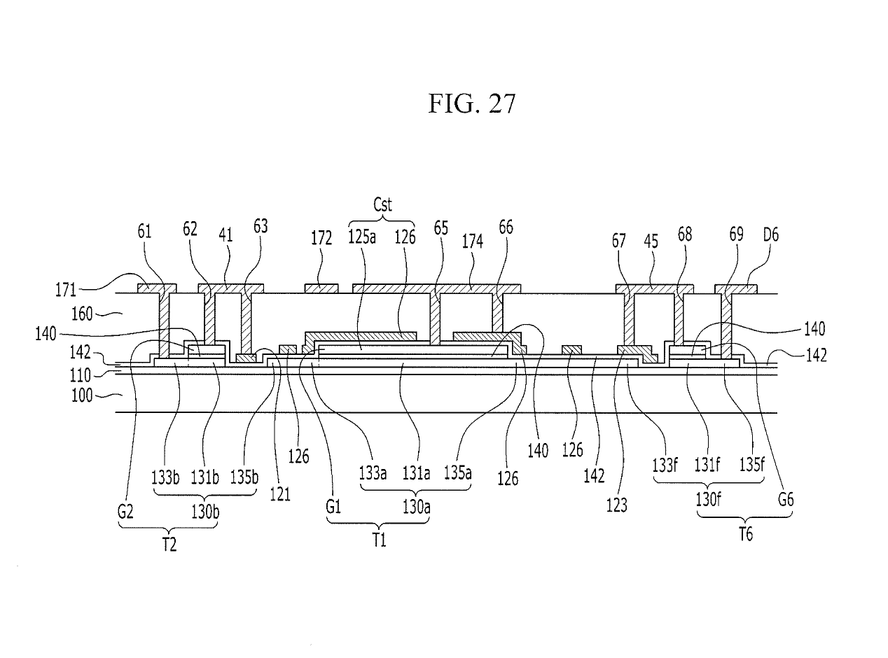

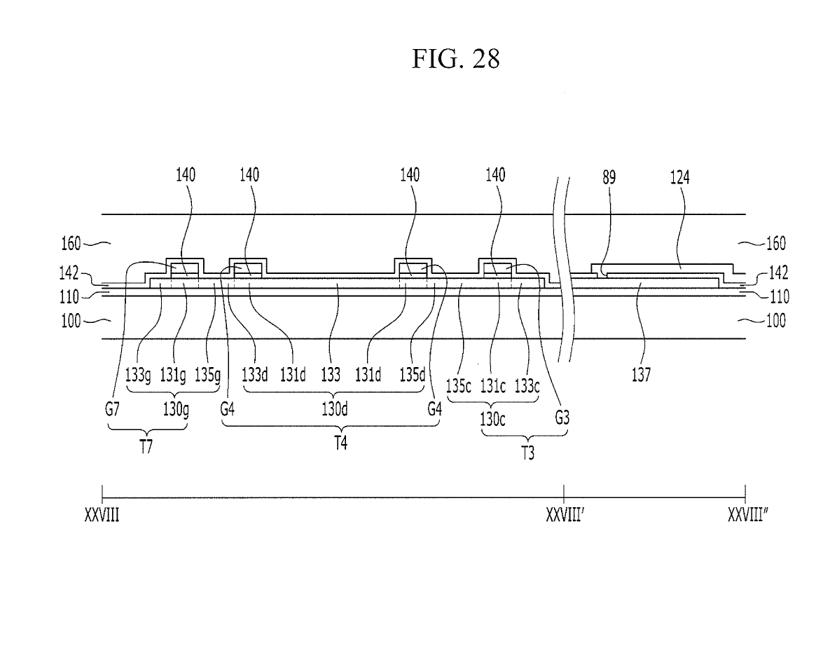

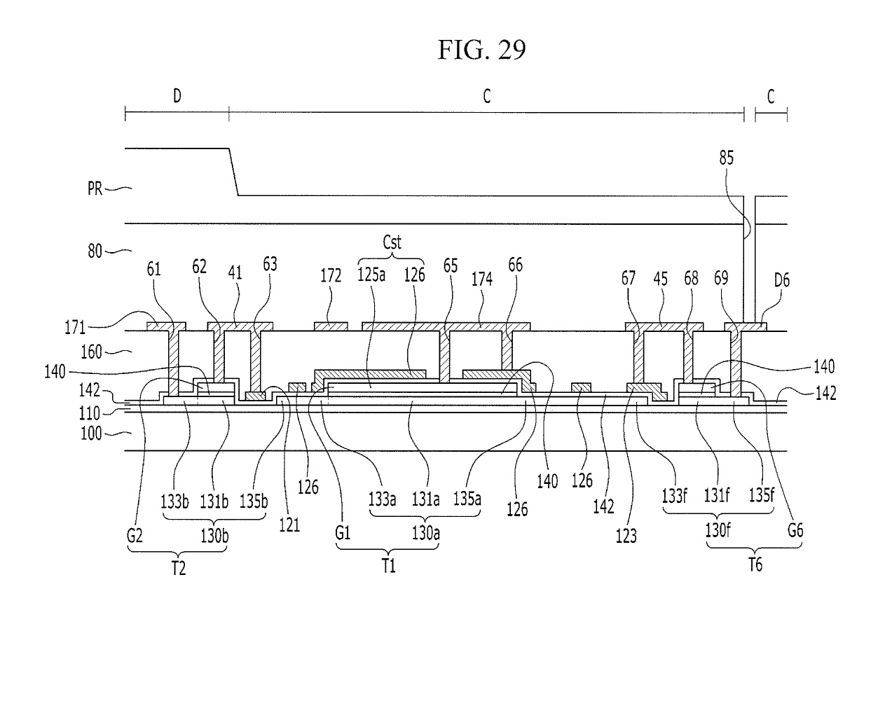

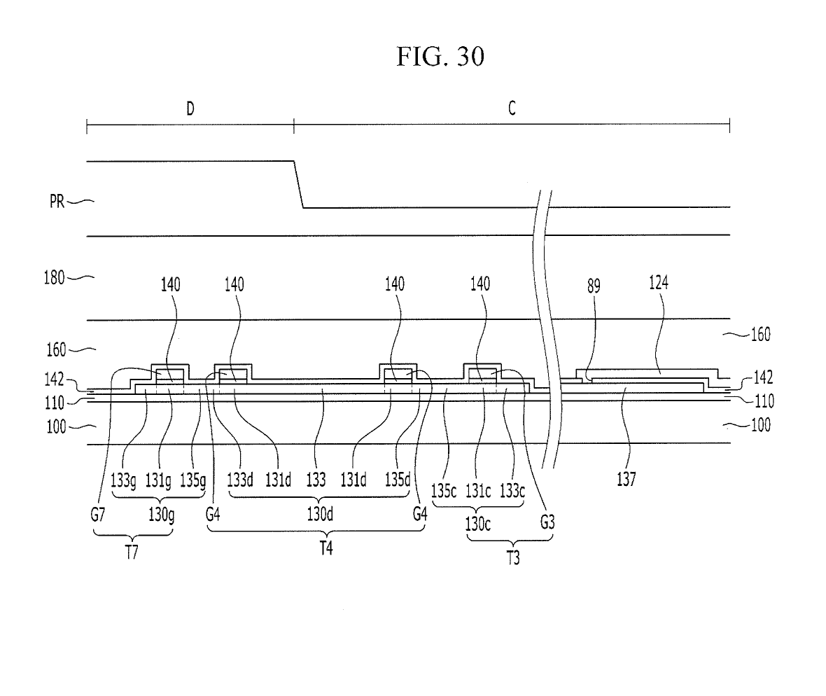

More specifically, FIG. 23 illustrates a layout view of an operation of the method. FIG. 24 illustrates a cross-sectional view taken along a line XXIV-XXIV in FIG. 23. FIG. 25 illustrates a cross-sectional view taken along lines XXV-XXV′ and XXV-XXV″ in FIG. 23. FIG. 26 is a layout view of an operation subsequent to FIG. 23. FIG. 27 illustrates a cross-sectional view taken along a line XXVII-XXVII in FIG. 26. FIG. 28 illustrates a cross-sectional view taken along lines XXVIII-XXVIII′ and XXVIII′-XXVIII″ in FIG. 26. FIG. 29 illustrates a layout view of an operation following FIG. 27. FIG. 30 illustrates a layout view of an operation following FIG. 28.

First, as shown in FIGS. 23 to 25, the buffer layer 110 is formed on the substrate 100. The semiconductor layer 130, which includes the driving semiconductor layer 130a, the switching semiconductor layer 130b, the compensation semiconductor layer 130c, the initialization semiconductor layer 130d, the operation control semiconductor layer 130e, the emission control semiconductor layer 130f, and the bypass semiconductor layer 130g, the first gate insulating layer 140, and the gate electrodes G1, G2, G3, G4, G5, and G6, are formed on the buffer layer 110.

Next, the semiconductor layer is doped with the conductive impurity to form the source region and the drain region. The method of forming the semiconductor layer, the first gate insulating layer, the gate electrode, the source region, and the drain region may be the same as that of FIGS. 6 to 13.

Next, as shown in FIGS. 26 to 28, the second gate insulating layer 142 is formed on the semiconductor layer 130, the first gate insulating layer 140, and the gate electrodes G1, G2, G3, G4, G5, and G6. The contact hole 89 exposing the semiconductor layer 137 is formed.

Also, the scan line 121, the previous scan line 122, the emission control line 123, and the initialization voltage line 124 are formed on the second gate insulating layer 142. The interlayer insulating layer 160 having the contact holes (61, 62, 63, 64, 65, 66, 67, 68, 69, 81, and 82) is formed on the scan line 121, the previous scan line 122, the emission control line 123, and the initialization voltage line 124, and the data line 171. The driving voltage line 172, the first connecting member 41, the second connecting member 42, the third connecting member 43, the fourth connecting member 44, the fifth connecting member 45, the sixth connecting member 46, and the seventh connecting member 174 are formed on the interlayer insulating layer 160.

Next, in FIGS. 29 and 30, the passivation layer 180 is formed on the data line 171, the driving voltage line 172, and the connecting members 41 to 47 and 174.

Next, the photosensitive film pattern PR having a different thickness is formed on the passivation layer 180. The photosensitive film pattern has a third portion corresponding to an opening region C where the opening is formed, and a fourth portion corresponding to the remaining region D except for the third portion and the contact hole. The exposed passivation layer 180 is etched using the photosensitive film pattern PR as a mask to form the contact hole 85 exposing emission control drain electrode D6.

Next, the photosensitive film pattern of the opening region C is removed by the etch back, and the opening 351 is formed using the photosensitive film pattern of the remaining region D as a mask.

Next, after removing the photosensitive film pattern, a metal layer is formed and patterned on the passivation layer 180 to form the first electrode 191 in the opening 351. Then, the organic emission layer 370 and the second electrode 270 are formed on the first electrode 191.

On the other hand, before removing the photosensitive film pattern of the remaining region, the metal layer may be formed on the passivation layer 180 including the photosensitive film pattern. The photosensitive film pattern may be removed by a remaining process to form the first electrode 191.

By way of summation and review, an organic light emitting diode display may be classified into a passive matrix type and an active matrix type based on the driving method that is used. An active matrix type of organic light emitting display includes an organic light emitting diode, a thin film transistor (TFT), and a capacitor for each pixel which are used to independently control the pixel. Such an OLED display requires a photolithography process using a plurality of masks according to a structure. However, as the number of mask processes increases, process time and process production cost also increase.

In accordance with one or more of the aforementioned embodiments, one or more semiconductor layers and/or one or more gate electrodes of driving and switching transistors of each pixel are simultaneously formed. This reduces the number of masks that are used during manufacture, and thus manufacturing costs and process time.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. An organic light emitting device, comprising:
a substrate;
a scan line and a previous scan line on the substrate to respectively transmit a scan signal and a previous scan signal;
a data line and a driving voltage line insulated from and intersecting the scan line and the previous scan line, the data line and the driving voltage line to respectively transmit a data signal and a driving voltage;
a switching transistor connected to the scan line and the data line, the switching transistor including a switching semiconductor layer, a switching channel region, and a switching gate electrode;
a driving transistor connected to the switching transistor and including a driving semiconductor layer, a driving channel region, and a driving gate electrode, the driving semiconductor layer and the switching semiconductor layer formed of a same layer;
a first gate insulating layer; and
an organic light emitting diode connected to the driving transistor,
wherein the driving semiconductor layer is curved,
wherein the first gate insulating layer is between the switching channel region and the switching gate electrode and between the driving channel region and the driving gate electrode,
wherein the first gate insulating layer has substantially a same plane shape as the switching gate electrode and the driving gate electrode, and
wherein an edge of the first gate insulating layer and an edge of the switching gate electrode and the driving gate electrode at least partially overlap.

2. The device as claimed in claim 1, further comprising:
a second gate insulating layer on the substrate including the switching gate electrode and the driving gate electrode; and
a first connector formed with a same layer as the data line, wherein the first connector connects the scan line on the second gate insulating layer and the switching gate electrode on the first gate insulating layer through a contact hole.

3. The device as claimed in claim 2, wherein:
the previous scan line is on the second gate insulating layer, and
the driving gate electrode is electrically connected to the previous scan line.

4. The device as claimed in claim 3, further comprising:
an initialization transistor to turn on based on a previous scan signal from the previous scan line and to transmit an initialization voltage to the driving gate electrode; and
a second connector formed with the same layer as the data line, wherein the second connector connects the previous scan line and an initialization gate electrode of the initialization transistor through a contact hole.

5. The device as claimed in claim 3, further comprising:
a passivation layer on the data line and the driving voltage line and having an opening, and
the organic light emitting diode includes a first electrode at a boundary line of the opening and electrically connected to the driving transistor,
an organic emission layer on the first electrode, and
a second electrode on the organic emission layer.

6. The device as claimed in claim 5, further comprising:
an emission control line on the second gate insulating layer;
a third connector and a fourth connector formed with the same layer as the data line;
an operation control transistor to turn on based on an emission control signal transmitted to the emission control line and to transmit a driving voltage transmitted by the driving voltage line to the driving transistor; and
an emission control transistor to turn on by the emission control signal and to transmit the driving voltage from the driving transistor to the organic light emitting diode, wherein the third connector connects the emission control line and the gate electrode of the operation control transistor through the contact hole, and the fourth connector connects the emission control line and the gate electrode of the emission control transistor through the contact hole.

7. The device as claimed in claim 6, wherein the first electrode is connected to a drain electrode of the emission control transistor through the contact hole in the passivation layer.

8. The device as claimed in claim 7, further comprising:
an initialization voltage line on the second gate insulating layer,
wherein the initialization voltage line is to transmit an initialization voltage to initialize the driving transistor.

9. The device as claimed in claim 6, wherein the semiconductor layer of the driving transistor, the switching transistor, the operation control transistor, and the emission control transistor are connected.

10. The device as claimed in claim 1, further comprising:
a storage capacitor including a first plate on the first gate insulating layer and overlapping the driving semiconductor layer, and a second plate on the second gate insulating layer covering the first plate and overlapping the first plate, wherein the second plate is the driving gate electrode.

11. A method for manufacturing an organic light emitting device, the method comprising:
depositing a polysilicon layer, an amorphous silicon layer, and a metal layer on a substrate;
forming a first photosensitive film pattern on the metal layer, the first photosensitive film including a first portion and a second portion thicker than the first portion;
etching the metal layer, the amorphous silicon layer, and the polysilicon layer using the first photosensitive film pattern as a mask to form a metal layer pattern, an insulating layer pattern, and a semiconductor layer;
etching the metal and insulating layer patterns using the second portion as a mask after removing the first portion to form a driving gate electrode, a switching gate electrode, and a first gate insulating layer;
doping an impurity into the semiconductor layer after removing the first photosensitive film pattern to form a source region and a drain region;
forming a second gate insulating layer on the driving gate electrode and the switching gate electrode;
forming a scan line and a previous scan line on the second gate insulating layer;
forming an interlayer insulating layer on the scan line and the previous scan line; and
forming a first connector connecting the scan line and the switching gate electrode through a contact hole and a data line and a driving voltage line intersecting the scan line and the previous scan line on the interlayer insulating layer.

12. The method as claimed in claim 11, further comprising after forming the data line and the driving voltage line:
forming a passivation layer on the data line and the driving voltage line;
forming a first electrode receiving a driving signal from the driving voltage line on the passivation layer;
forming a pixel definition layer having an opening exposing the first electrode on the first electrode;
forming an organic emission layer in the opening; and
forming a second electrode on the organic emission layer.

13. The method as claimed in claim 11, further comprising:
etching the metal and insulating layer patterns using the second portion as a mask to form an initialization gate electrode; and
forming a second connector connecting the previous scan line and the initialization gate electrode through a contact hole on the interlayer insulating layer.

14. The method as claimed in claim 13, further comprising:
etching the metal and insulating layer patterns using the second portion as a mask to form an operation control gate electrode and an emission control gate electrode;
forming an emission control line on the second gate insulating layer; and
forming a third connector connecting the emission control line and the operation control gate electrode through a contact hole and a fourth connector connecting the emission control line and the emission control gate electrode through a contact hole on the interlayer insulating layer.

15. The method as claimed in claim 14, further comprising after forming the data line and the driving voltage line:
forming a passivation layer on the data line and the driving voltage line;
forming a second photosensitive film pattern on the passivation layer, the second photosensitive film including a third portion and a fourth portion thicker than the third portion;
etching the passivation layer using the second photosensitive film pattern as a mask to form a contact hole for a pixel exposing the emission control gate electrode;
removing a portion of the passivation layer using the fourth portion as a mask after removing the third portion to form an opening;
forming a first electrode in the opening;
forming an organic emission layer on the first electrode; and
forming a second electrode on the organic emission layer.

16. A pixel, comprising:
a switching transistor connected to a scan line and data line, the switching transistor including a switching semiconductor layer, a switching channel region, and a switching gate electrode; and
a driving transistor connected to the switching transistor and including a driving semiconductor layer, a driving channel region, and a driving gate electrode, wherein the driving semiconductor layer and the switching semiconductor layer correspond to different regions of a same first layer, and wherein the switching gate electrode and the driving gate electrode correspond to different regions of a same second layer on the first layer.

17. The pixel as claimed in claim 16, the driving semiconductor layer has a non-linear shape.

18. The pixel as claimed in claim 16, further comprising:
a gate insulating layer to insulate the switching and driving gate electrodes, wherein the gate insulating layer has substantially a same shape as the switching and driving gate electrodes.

19. The pixel as claimed in claim 18, wherein the gate insulating layer has substantially a same shape as the switching gate electrode and the driving gate electrode.

20. The pixel as claimed in claim 19, wherein an edge of the gate insulating layer and an edge of the switching gate electrode and the driving gate electrode at least partially overlap.
